(19) United States
(12) Patent Application Publication
(10) Pub. No.: US 2024/0074233 A1
(43) Pub. Date: Feb. 29, 2024

(54) DISPLAY PANEL AND METHOD OF MANUFACTURING THE SAME

(71) Applicant: Samsung Display Co., Ltd., Yongin-Si (KR)

(72) Inventors: SANGJIN PARK, Yongin-si (KR); MINSANG KIM, Yongin-si (KR); SANGHYUK LEE, Yongin-si (KR); MINGYU JUNG, Yongin-si (KR)

(21) Appl. No.: 18/128,363

(22) Filed: Mar. 30, 2023

(30) Foreign Application Priority Data
Aug. 23, 2022 (KR) 10-2022-0105538

(51) Int. Cl. H10K 59/121; H01L 29/786; H10K 59/12

(52) U.S. Cl. CPC H10K 59/1213; H01L 29/78672; H01L 29/7869; H01L 29/78696; H10K 59/1201

(57) ABSTRACT

A display panel of the inventive concept includes a light emitting element, a pixel circuit including a first transistor and electrically connected to the light emitting element, and a first insulating layer. The first transistor includes a first semiconductor pattern arranged under the first insulating layer and including a first source region, a first drain region, and a first channel region arranged between the first source region and the first drain region, and a first gate arranged on the first insulating layer and overlapping the first channel region. The first insulating layer includes a first region overlapping a normal region of the first gate and the first source region, and a second region which overlaps a protruding region of the first gate, has a thickness greater than that of the first region, and is disposed close to the first drain region than the first region.

### CROSS-REFERENCE TO RELATED APPLICATIONS

This U.S. non-provisional patent application claims priority under 35 U.S.C. § 119 to Korean Patent Application No. 10-2022-0105538, filed on Aug. 23, 2022, the entire contents of which are hereby incorporated by reference.

### BACKGROUND

The present disclosure herein relates to a display panel and a method of manufacturing the same.

A display device includes a display panel, and the display panel includes a light emitting element and a pixel circuit for controlling an electrical signal applied to the light emitting element. The pixel circuit may include at least two transistors. As high-resolution display panels are developed, design limitations occur when designing transistors.

### SUMMARY

The present disclosure provides a display panel having a high resolution and provides a display panel including a transistor having improved reliability.

The present disclosure provides a method of manufacturing a high-resolution display panel that includes a transistor with improved reliability.

A display panel according to the inventive concept includes a light emitting element, a pixel circuit including a first transistor and electrically connected to the light emitting element, and a first insulating layer. The first transistor includes a first semiconductor pattern arranged under the first insulating layer and including a first source region, a first drain region, and a first channel region arranged between the first source region and the first drain region, and a first gate arranged on the first insulating layer and overlapping the first channel region. The first insulating layer includes a first region overlapping a normal region of the first gate and the first source region, and a second region which overlaps a protruding region of the first gate, has a thickness greater than that of the first region, and is disposed close to the first drain region than the first region.

The first region may have a uniform thickness and overlaps the first portion of the first gate and the first source region.

The first insulating layer may have a uniform thickness in the second region and the first region and the second region form a step in a region overlapping the channel region.

The second region may include a first sub-region having a first thickness and forming a step with the first region and a second sub-region having a second thickness larger than the first thickness and forming a step with the first sub-region.

The first insulating layer in the second region may have a thickness gradually increasing towards the first drain region

The first insulating layer may further include a third region overlapping the first drain region and having a smaller thickness than the second region, wherein the second region may form a step with the third region.

A thickness of the first insulating layer in the third region may be the same as the thickness of the first insulating layer in the first region.

In a cross-sectional view, a length of the second region in a channel length direction may be at most half of a length of the first channel region in the channel length direction.

A thickness of the first insulating layer in the second region may be at most two times greater than the thickness of the first insulating layer in the first region.

The display panel may further include a second transistor, wherein the second transistor may include a second semiconductor pattern arranged on the same layer as the first semiconductor pattern and including a second source region, a second drain region, and a second channel region arranged between the second source region and the second drain region, and a second gate overlapping the second channel region and arranged on the same layer as the first gate. The first semiconductor pattern and the second semiconductor pattern may include the same material and include any one of polysilicon and oxide semiconductor.

The first region may further overlap a normal region of the second gate and the second source region, and the second region may further overlap a protruding region of the second gate and may be disposed close to the second drain region than the first region overlapping the normal region of the second gate and the second source region.

The first insulating layer may have a uniform thickness in a region overlapping the second semiconductor pattern.

The first transistor may be a switching transistor and the second transistor may be a driving transistor.

The display panel may further include an upper insulating layer arranged on the first gate and a second transistor, wherein the second transistor may include a second semiconductor pattern arranged between the first insulating layer and the upper insulating layer and including a second source region, a second drain region, and a second channel region arranged between the second source region and the second drain region, and a second gate arranged on the upper insulating layer and overlapping the second channel region. The first semiconductor pattern may include polysilicon, and the second semiconductor pattern may include an oxide semiconductor.

The upper insulating layer may include a first region overlapping a normal region of the second gate and the second source region, and a second region which overlaps a protruding region of the second gate, has a thickness greater than that of the first region of the upper insulating layer, and is disposed close to the second drain region than that of the first region of the upper insulating layer.

The upper insulating layer may have a uniform thickness in a region overlapping the second semiconductor pattern.

The display panel may further include a lower insulating layer arranged under the first semiconductor pattern and a second transistor, wherein the second transistor may include a second semiconductor pattern arranged under the lower insulating layer and including a second source region, a second drain region, and a second channel region arranged between the second source region and the second drain region, and a second gate arranged between the lower insulating layer and the first insulating layer and overlapping the second channel region. The lower insulating layer may include a first region overlapping a normal region of the second gate and the second source region, and a second region which overlaps a protruding region of the second gate, has a thickness greater than that the first region of the lower insulating layer, and is disposed close to the second drain region than the first region of the lower insulating layer, and the first semiconductor pattern may include an oxide semiconductor and the second semiconductor pattern may include a silicon semiconductor.

The display panel may further include a second insulating layer arranged on the first insulating layer and covering the first gate, a first connection electrode arranged on the second insulating layer and connected to the first source region through a first contact hole formed in the first insulating layer and the second insulating layer, and a second connection electrode arranged on the second insulating layer and connected to the first drain region through a second contact hole formed in the first and second insulating layers.

A display panel according to the inventive concept includes a base layer, a light emitting element arranged on the base layer, a pixel circuit including a transistor and electrically connected to the light emitting element, and an insulating layer arranged on the base layer. The transistor includes a semiconductor pattern arranged between the base layer and the insulating layer and including a source region, a drain region, and a channel region arranged between the source region and the drain region, and a gate overlapping the channel region and arranged on the insulating layer. The gate may include a first edge disposed adjacent to the source region and a second edge disposed adjacent to the drain region, and a distance from an upper portion of the semiconductor pattern to an upper portion of the second edge is larger than a distance from an upper portion of the semiconductor pattern to the second edge.

A method of manufacturing a display panel according to the inventive concept includes forming a preliminary semiconductor pattern on a base layer, forming a preliminary insulating layer on the preliminary semiconductor pattern, forming an insulating layer including a first region and a second region having a thickness greater than that of the first region through a photolithography process, forming a gate overlapping a portion of the first region and the second region on the insulating layer, and forming, from the preliminary semiconductor pattern, a semiconductor pattern including a channel region overlapping the gate and a source region and a drain region which extend in opposite directions with the channel region disposed therebetween. The second region may be disposed close to the drain region than the first region.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a plan view of a display device according to an embodiment of the inventive concept;

FIG. 2 is a cross-sectional view of a display panel according to an embodiment of the inventive concept;

FIG. 3A is a block diagram of a display device according to an embodiment of the inventive concept;

FIG. 3B is an equivalent circuit diagram of a pixel according to an embodiment of the inventive concept;

FIG. 4A is a cross-sectional view of a display panel according to an embodiment of the inventive concept;

FIG. 4B is an enlarged cross-sectional view of a transistor in the area AA′ of FIG. 4A, according to an embodiment of the inventive concept;

FIG. 5A and FIG. 5B are enlarged cross-sectional views of transistors in an area corresponding to the area AA′ of FIG. 4A, according to embodiments of the inventive concept;

FIG. 6 is a cross-sectional view of a display panel according to an embodiment of the inventive concept;

FIG. 7 is cross-sectional view of a display panel according to an embodiment of the inventive concept;

FIG. 8 is a cross-sectional view of a display panel according to an embodiment of the inventive concept;

FIG. 9 is a cross-sectional view of a display panel according to an embodiment of the inventive concept;

FIG. 10 is a cross-sectional view of a display panel according to an embodiment of the inventive concept; and

FIG. 11A, 11B, 11C, 11D, 11E, 11F, 11G and FIG. 11H are cross-sectional views illustrating a method of manufacturing a display panel according to an embodiment of the inventive concept.

### DETAILED DESCRIPTION

It will be understood that when an element or layer is referred to as being “on”, “connected to”, or “coupled to” another element or layer, it can be directly on, connected to, or coupled to the other element or layer, or intervening elements or layers may be present.

Like reference numerals refer to like elements throughout this specification. In the figures, the thicknesses, ratios, and dimensions of elements are exaggerated for effective description of the technical contents. As used herein, the term “and/or” includes any and all combinations of one or more of the associated listed items.

It will be understood that, although the terms first, second, etc. may be used herein to describe various elements, components, regions, layers, and/or sections, these elements, components, regions, layers, and/or sections should not be limited by these terms. These terms are only used to distinguish one element, component, region, layer, or section from another element, component, region, layer, or section. Thus, a first element, component, region, layer, or section discussed below could be termed a second element, component, region, layer, or section without departing from the teachings of the present inventive concept. As used herein, the singular forms, “a”, “an”, and “the” are intended to include the plural forms as well, unless the context clearly indicates otherwise.

Spatially relative terms, such as “beneath”, “below”, “lower”, “above”, and “upper”, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures.

It will be further understood that the terms “include” or “have”, when used in this specification, specify the presence of stated features, integers, steps, operations, elements, components, and/or groups thereof, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having meaning that is consistent with their meaning in the context of the relevant art and should not be interpreted in an overly idealized or overly formal sense unless expressly so defined herein.

Hereinafter, embodiments of the inventive concept will be described in detail with reference to the accompanying drawings.

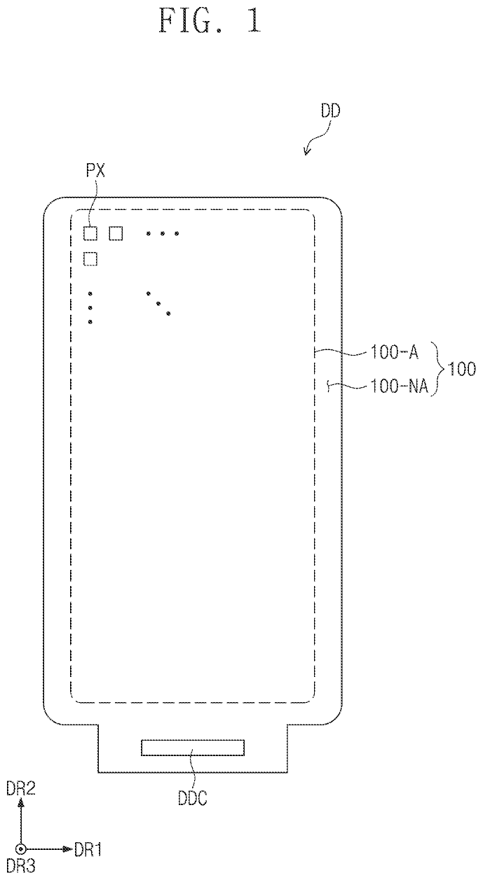

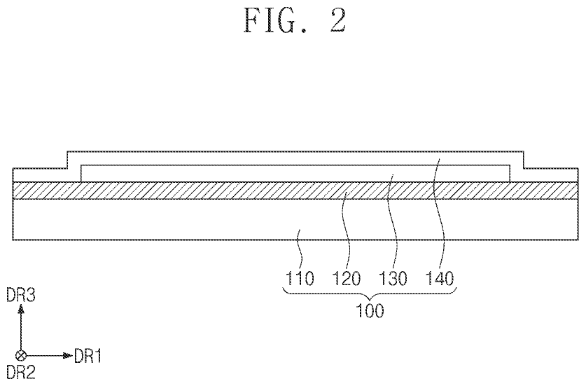

FIG. 1 is a plan view of a display device according to an embodiment of the inventive concept. FIG. 2 is a cross-sectional view of a display panel according to an embodiment of the inventive concept.

Referring to FIG. 1, a display device DD may include a display panel 100. The display panel 100 may include a display area 100-A and a non-display area 100-NA. The non-display area 100-NA may be disposed adjacent to the display area 100-A and may surround at least a portion of the display area 100-A. Pixels PX may be disposed in the display area 100-A and may not be disposed in the non-display area 100-NA.

The display area 100-A may include a plane defined by a first direction DR1 and a second direction DR2. A thickness direction of the display panel 100 may be parallel to a third direction DR3 which is a normal direction of the display area 100-A. A front surface (or a top surface) and a rear surface (or a bottom surface) of each of members constituting the display panel 100 may be defined on the basis of the third direction DR3.

The display panel 100 may be a light emitting display panel. For example, the display panel 100 may be an organic light emitting display panel, an inorganic light emitting display panel, a micro-LED display panel, or a nano-LED display panel. The display panel 100 may be flexible. Although not illustrated, the display panel 100 may be folded about at least one folding axis. A folding area may cross the display area 100-A.

The display device DD may further include a data driving circuit DDC. The data driving circuit DDC may be mounted on the display panel 100. In an embodiment, the data driving circuit DDC may be disposed on one side of the non-display area 100-NA. A detailed description of the data driving circuit DDC will be given later.

Referring to FIG. 2, the display panel 100 may include a base layer 110, a circuit layer 120, a light emitting element layer 130, and an encapsulation layer 140. Unlike the illustration of FIG. 2, another functional layer may be further disposed between two adjacent layers among the base layer 110, the circuit layer 120, the light emitting element layer 130, and the encapsulation layer 140.

The base layer 110 may provide a base surface on which the circuit layer 120 is disposed. The base layer 110 may be a flexible substrate capable of bending, folding, rolling, or the like. The base layer 110 may be a glass substrate, a metal substrate, a polymer substrate, or the like. However, an embodiment is not limited thereto, and the base layer 110 may include an inorganic layer, an organic layer, or a composite material layer.

The base layer 110 may include multiple layers. For example, the base layer 110 may include a first synthetic resin layer, a multilayer or single-layer inorganic layer, and a second synthetic resin layer disposed on the multilayer or single-layer inorganic layer. Each of the first synthetic resin layer and the second synthetic resin layer may include a polyimide-based resin and is not particularly limited.

The circuit layer 120 may be disposed on the base layer 110. The circuit layer 120 may include at least one insulating layer, at least one semiconductor pattern, at least one conductive pattern, at least one signal line, and the like.

The light emitting element layer 130 may be disposed on the circuit layer 120. The light emitting element layer 130 may include a light emitting element. For example, the light emitting element may include an organic light emitting material, an inorganic light emitting material, an organic-inorganic light emitting material, a quantum dot, a quantum rod, a micro-LED, or a nano-LED.

The encapsulation layer 140 may be disposed on the light emitting element layer 130. The encapsulation layer 140 may protect the light emitting element layer 130 from foreign matter such as moisture, oxygen, and dust particles. The encapsulation layer 140 may include at least one inorganic layer. The encapsulation layer 140 may include a structure in which an inorganic layer, an organic layer, and an inorganic layer are sequentially laminated.

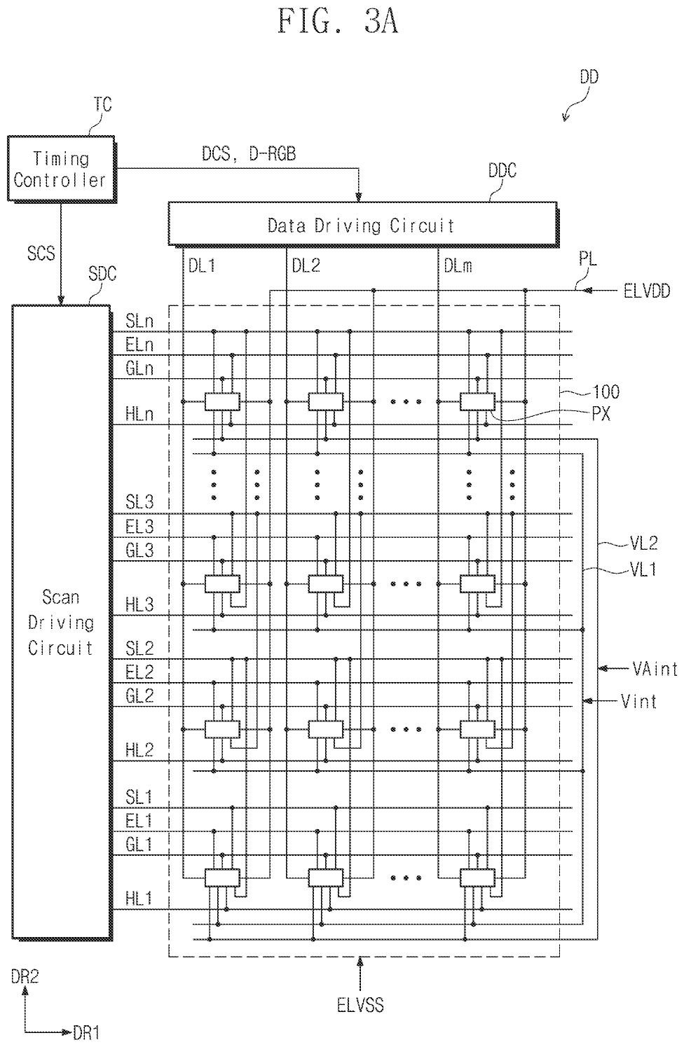

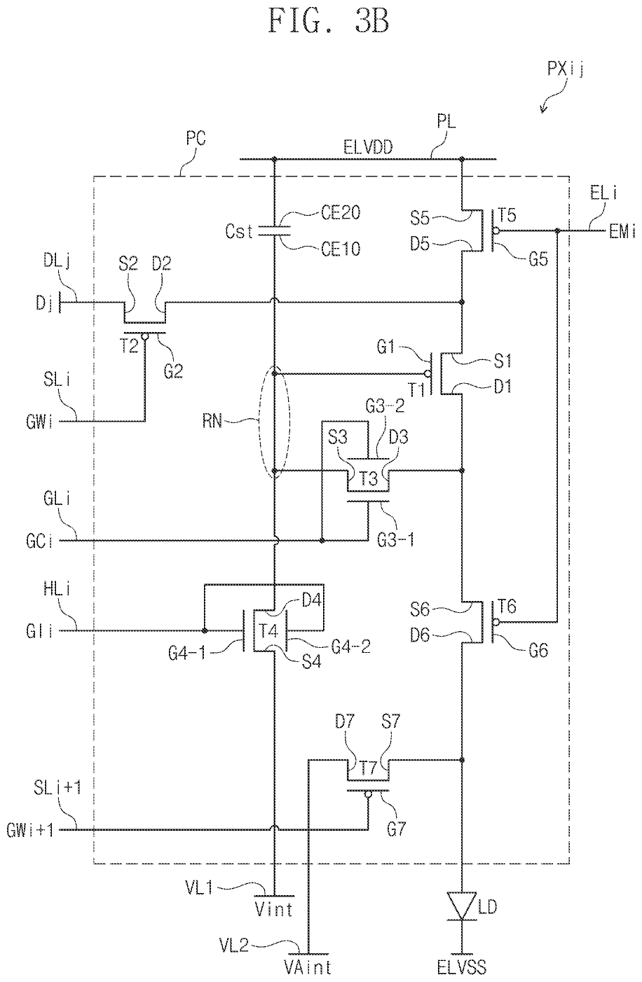

FIG. 3A is a block diagram of a display device according to an embodiment of the inventive concept. FIG. 3B is an equivalent circuit diagram of a pixel according to an embodiment of the inventive concept.

The display device DD may include a timing controller TC, a scan driving circuit SDC, a data driving circuit DDC, and the display panel 100. At least one of the timing controller TC, the scan driving circuit SDC, or the data driving circuit DDC may be provided in the form of a driving chip or may be directly provided on the display panel 100.

The timing controller TC may receive input image signals and generate image data D-RGB by converting the data format of the input image signals according to an interface specification between the timing controller TC and the data driving circuit DDC. The timing controller TC outputs the image data D-RGB and various control signals DCS and SCS.

The scan driving circuit SDC may receive a scan control signal SCS from the timing controller TC. The scan control signal SCS may include a vertical start signal for starting the operation of the scan driving circuit SDC, a clock signal for determining output timing of signals, and the like. The scan driving circuit SDC may generate a plurality of scan signals and may sequentially output the scan signals to corresponding signal lines of signal lines SL1 to SLn, GL1 to GLn, and HL1 to HLn. In addition, the scan driving circuit SDC may generate a plurality of emission control signals in response to the scan control signal SCS and may output each of the emission control signals to a corresponding one of emission lines EL1 to ELn.

Although the plurality of scan signals and the plurality of emission control signals are illustrated in FIG. 3A to be outputted from one scan driving circuit SDC, an embodiment is not limited thereto. For example, the scan driving circuit SDC may be provided in plurality. Each of the plurality of scan driving circuits may generate and output a portion of the plurality of scan signals and a portion of the plurality of emission control signals. In addition, a driving circuit generating and outputting the plurality of scan signals and a driving circuit generating and outputting the plurality of emission control signals may be provided separately.

The data driving circuit DDC may receive a data control signal DCS and the image data D-RGB from the timing controller TC. The data driving circuit DDC may convert the image data D-RGB into data signals and output the data signals to a plurality of data lines DL1 to DLm to be described later. The data signals may be analog voltages corresponding to gradation values of the image data D-RGB.

A plurality of groups of signal lines may include scan lines SL1 to SLn of a first group, scan lines GL1 to GLn of a second group, scan lines HL1 to HLn of a third group, the emission lines EL1 to ELn, the data lines DL1 to DLm, a first voltage line PL, a second voltage line VL1, and a third voltage line VL2. The scan lines SL1 to SLn of the first group, the scan lines GL1 to GLn of the second group, the scan lines HL1 to HLn of the third group, and the emission lines EL1 to ELn may each extend in the first direction DR1 and may be arranged in the second direction DR2 crossing the first direction DR1. The plurality of data lines DL1 to DLm may cross the scan lines SL1 to SLn of the first group, the scan lines GL1 to GLn of the second group, the scan lines HL1 to HLn of the third group, and the emission lines EL1 to ELn in an insulated manner.

Each of the first voltage line PL, the second voltage line VL1, and the third voltage line VL2 may include at least one of a component extending in the first direction DR1 or a component extending in the second direction DR2. Each of the first voltage line PL, the second voltage line VL1, and the third voltage line VL2 may include the component extending in the first direction DR1 and the component extending in the second direction DR2. The structures and shapes of the first voltage line PL, the second voltage line VL1, and the third voltage line VL2 may be designed independently of each other.

Each of the plurality of pixels PX may be electrically connected to corresponding signal lines among the aforementioned signal lines SL1 to SLn, GL1 to GLn, and HL1 to HLn. A connection relationship between the pixels PX and the signal lines may be changed according to a configuration of a driving circuit of each of the pixels PX.

The first voltage line PL may receive a first power supply voltage ELVDD. A second power supply voltage ELVSS may be applied to the display panel 100. The second power supply voltage ELVSS may have a level lower than that of the first power supply voltage ELVDD.

The second voltage line VL1 may receive a first initialization voltage Vint. The first initialization voltage Vint may have a level lower than that of the first power supply voltage ELVDD. The third voltage line VL2 may receive a second initialization voltage VAint. The second initialization voltage VAint may have a level lower than that of the first power supply voltage ELVDD. The first initialization voltage Vint and the second initialization voltage VAint may be bias voltages having a constant level. The first initialization voltage Vint and the second initialization voltage VAint may have different levels. The second initialization voltage VAint may have a voltage lower than that of the first initialization voltage Vint.

The plurality of pixels PX may include a plurality of groups generating light of different colors. For example, the plurality of pixels PX may include red pixels generating red light, green pixels generating green light, and blue pixels generating blue light. A light emitting element of each of the red pixels, a light emitting element of each of the green pixels, and a light emitting element of each of the blue pixels may include light emitting layers including different materials.

FIG. 3B illustrates, as an example, a pixel PXij connected to an i-th scan line SLi of the first group among the scan lines SL1 to SLn of the first group and connected to a j-th data line DLj among the plurality of data lines DL1 to DLm. The pixel PXij may include a pixel driving circuit PC (hereinafter a pixel circuit PC) and a light emitting element LD.

The i-th scan line SLi of the first group, an (i+1)-th scan line SLi+1 of the first group, an i-th scan line GLi of the second group, an i-th scan line HLi of the third group, and an i-th emission line ELi may respectively transmit an i-th first scan signal GWi, an (i+1)-th first scan signal GWi+1, an i-th second scan signal GCi, an i-th third scan signal GIi, and an emission signal EMi. The j-th data line DLj may transmit a data signal Dj. The data signal Dj may have a voltage level corresponding to the image data D-RGB (see FIG. 3A) inputted to the display device DD (see FIG. 3A). The first to third voltage lines PL, VL1, and VL2 may transmit the first power supply voltage ELVDD, the first initialization voltage Vint, and the second initialization voltage VAint, respectively.

In an embodiment, the pixel circuit PC may include first to seventh transistors T1 to T7 and a capacitor Cst. The first transistor T1, the second transistor T2, and the fifth to seventh transistors T5 to T7 may be P-type transistors, and the third transistor T3 and the fourth transistor T4 may be N-type transistors. However, an embodiment of the inventive concept is not limited thereto, and the first to seventh transistors T1 to T7 may be implemented as either P-type transistors or N-type transistors.

Hereinafter, an input region (or an input electrode) of the N-type transistor is described as a drain (or a drain region), an input region of the P-type transistor is described as a source (or a source region), an output region (or an output electrode) of the N-type transistor is described as a source (or a source region), and an output region of the P-type transistor is described as a drain (or a drain region). Meanwhile, at least one of the first to seventh transistors T1 to T7 may be omitted.

In this embodiment, the first transistor T1, the second transistor T2, and the fifth to seventh transistors T5 to T7 may be silicon transistors. For example, each of the first transistor T1, the second transistor T2, and the fifth to seventh transistors T5 to T7 may be a transistor having a semiconductor layer including low-temperature polycrystalline silicon (LTPS). The third transistor T3 and the fourth transistor T4 may be oxide transistors. However, an embodiment of the inventive concept is not limited thereto, and the first to seventh transistors T1 to T7 may be implemented as either silicon transistors or oxide transistors.

The first transistor T1 may be a driving transistor, and the second transistor T2 may be a switching transistor. The capacitor Cst may be electrically connected between the first voltage line PL receiving the first power supply voltage ELVDD and a reference node RN. The capacitor Cst may include a first electrode CE10 electrically connected to the reference node RN and a second electrode CE20 electrically connected to the first voltage line PL.

The first transistor T1 may be electrically connected between the first voltage line PL and one electrode (e.g., an anode) of the light emitting element LD. A source S1 of the first transistor T1 may be electrically connected to the first voltage line PL. As used herein, “electrically connected between a transistor and a signal line or between a transistor and another transistor” means that “the source, drain, or gate of the transistor has an integral shape with the signal line, or the transistors are connected through a connection electrode”. Another transistor may be disposed or omitted between the source S1 of the first transistor T1 and the first voltage line PL.

A drain D1 of the first transistor T1 may be electrically connected to the anode of the light emitting element LD. Another transistor may be disposed or omitted between the drain D1 of the first transistor T1 and the anode of the light emitting element LD. A gate G1 of the first transistor T1 may be electrically connected to the reference node RN.

The second transistor T2 may be electrically connected between the j-th data line DLj and the source S1 of the first transistor T1. A source S2 of the second transistor T2 is electrically connected to the j-th data line DLj, and a drain D2 of the second transistor T2 is electrically connected to the source S1 of the first transistor T1. A gate G2 of the second transistor T2 may be electrically connected to the i-th scan line SLi of the first group.

The third transistor T3 may be electrically connected between the reference node RN and the drain D1 of the first transistor T1. A drain D3 of the third transistor T3 may be electrically connected to the drain D1 of the first transistor T1, and a source S3 of the third transistor T3 may be electrically connected to the reference node RN. Gates G3-1 and G3-2 of the third transistor T3 may be electrically connected to the i-th scan line GLi of the second group. Although illustrated as including a plurality of gates, the third transistor T3 is not limited thereto and may include only one gate.

The fourth transistor T4 may be electrically connected between the reference node RN and the second voltage line VL1. A drain D4 of the fourth transistor T4 may be electrically connected to the reference node RN, and a source S4 of the fourth transistor T4 may be electrically connected to the second voltage line VL1. Gates G4-1 and G4-2 of the fourth transistor T4 may be electrically connected to the i-th scan line HLi of the third group. Although the fourth transistor T4 including a plurality of gates is illustrated, an embodiment is not limited thereto, and the fourth transistor T4 may include only one gate.

The fifth transistor T5 may be electrically connected between the first voltage line PL and the source S1 of the first transistor T1. A source S5 of the fifth transistor T5 may be electrically connected to the first voltage line PL, and a drain D5 of the fifth transistor T5 may be electrically connected to the source S1 of the first transistor T1. A gate G5 of the fifth transistor T5 may be electrically connected to the i-th emission line ELi.

The sixth transistor T6 may be electrically connected between the drain D1 of the first transistor T1 and the light emitting element LD. A source S6 of the sixth transistor T6 may be electrically connected to the drain D1 of the first transistor T1, and a drain D6 of the sixth transistor T6 may be electrically connected to the anode of the light emitting element LD. A gate G6 of the sixth transistor T6 may be electrically connected to the i-th emission line ELi. Alternatively, the gate G6 of the sixth transistor T6 may be connected to a signal line different from the line to which the gate G5 of the fifth transistor T5 is connected.

The seventh transistor T7 may be electrically connected between the drain D6 of the sixth transistor T6 and the third voltage line VL2. A source S7 of the seventh transistor T7 is electrically connected to the drain D6 of the sixth transistor T6, and a drain D7 of the seventh transistor T7 is electrically connected to the third voltage line VL2. A gate G7 of the seventh transistor T7 may be electrically connected to the (i+1)-th scan line SLi+1 of the first group.

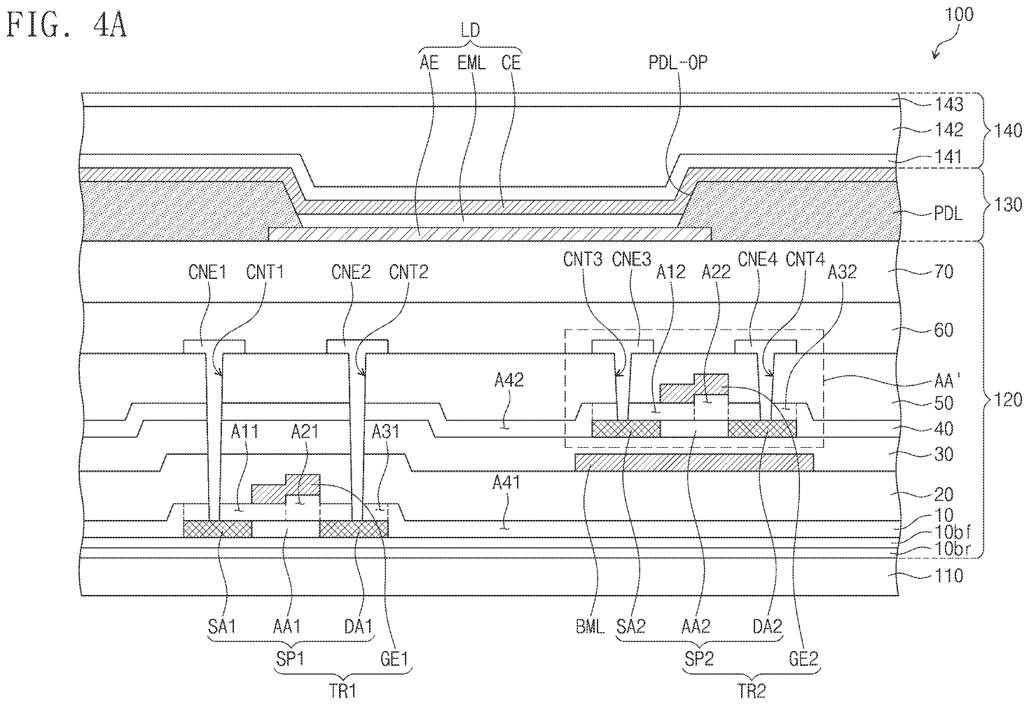

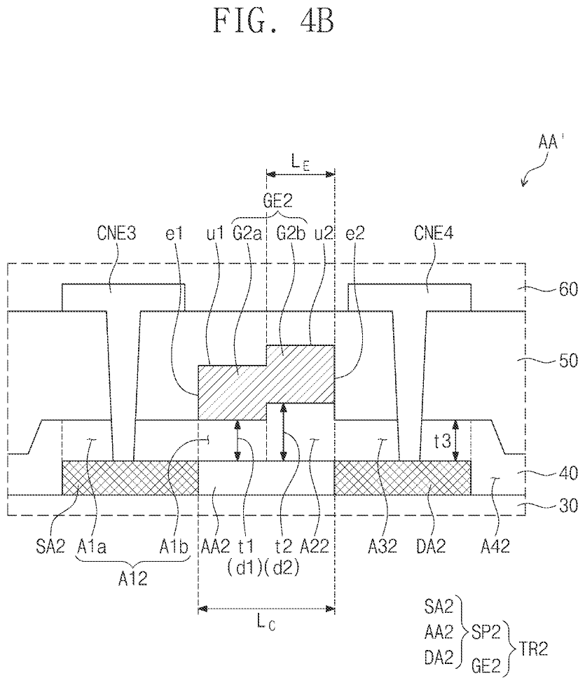

FIG. 4A is a cross-sectional view of a display panel according to an embodiment of the inventive concept. FIG. 4B is an enlarged cross-sectional view of a transistor in the area AA′ of FIG. 4A, according to an embodiment of the inventive concept. FIG. 4A is an enlarged view of a portion of the pixel PXij of FIG. 3B.

Referring to FIG. 4A, the display panel 100 may include the base layer 110, the circuit layer 120, the light emitting element layer 130, and the encapsulation layer 140.

The circuit layer 120 may include a barrier layer 10br, a buffer layer 10bf, first to fifth insulating layers 10 to 50, first and second organic insulating layers 60 and 70, first and second transistors TR1 and TR2, and connection electrodes CNE1, CNE2, CNE3, and CNE4.

The barrier layer 10br may be disposed on the base layer 110. The barrier layer 10br may prevent foreign matter from being introduced from the outside. The barrier layer 10br may include at least one inorganic layer. For example, the barrier layer 10br may include a silicon oxide layer and/or a silicon nitride layer. Each of the silicon oxide layer and the silicon nitride layer may be provided in plurality, and the silicon oxide layers and the silicon nitride layers may be alternately laminated.

The buffer layer 10bf may be disposed on the barrier layer 10br. The buffer layer 10bf may prevent metal atoms or impurities from diffusing from the base layer 110 to a first semiconductor pattern SP1 of the first transistor TR1 disposed thereon. The buffer layer 10bf may include at least one inorganic layer. The buffer layer 10bf may include a silicon oxide layer and/or a silicon nitride layer.

The first semiconductor pattern SP1 of the first transistor TR1 may be disposed on the buffer layer 10bf. The first semiconductor pattern SP1 may include a silicon semiconductor. For example, the silicon semiconductor may include amorphous silicon, polycrystalline silicon (i.e., polysilicon), or the like. The first semiconductor pattern SP1 may include low-temperature polysilicon. The first transistor TR1 of FIG. 4A may correspond to at least one of the first, second, fifth to seventh transistors T1, T2, T5, T6, and T7 described above with reference to FIG. 3B.

The first semiconductor pattern SP1 may have different electrical properties depending on whether doped or not. The first semiconductor pattern SP1 may include a first region having a high conductivity and a second region having a low conductivity. The first region may be a region doped with an N-type dopant or a P-type dopant. A P-type first region may be doped with the P-type dopant, and an N-type first region may be doped with the N-type dopant. The second region may be an undoped region or a region doped at a lower concentration than the first region.

The conductivity of the first region may be higher than that of the second region, and the first region may substantially serve as an electrode or a signal line. The second region may substantially correspond to a channel region (or an active region) of the transistor. A first source region SA1, a first channel region AA1, and a first drain region DA1 of the first transistor TR1 may be provided from the first semiconductor pattern SP1. The first source region SA1 and the first drain region DA1 may respectively extend in opposite directions from the first channel region AA1.

The first insulating layer 10 covering the first semiconductor pattern SP1 may be disposed on the buffer layer 10bf. The first insulating layer 10 may be an inorganic layer, and the first insulating layer 10 may be referred to as a first gate insulating layer. The first insulating layer 10 may include at least one of silicon oxide, silicon nitride, or silicon oxynitride. Although each of the first insulating layer 10 and the second to fifth insulating layers 20, 30, 40, and 50 to be described below may have a single-layer structure or a multilayer structure and may include at least one of the above-described materials, an embodiment of the inventive concept is not limited thereto.

In this embodiment, the first insulating layer 10 may include first to fourth regions A11, A21, A31, and A41. The second region A21 of the first insulating layer 10 may be thicker than the other portions of the first insulating layer 10. The second region A21 may be overlapped with the first semiconductor pattern SP1. A detailed description thereof will be given later.

A first gate GE1 of the first transistor TR1 may be disposed on the first insulating layer 10. In an embodiment, a portion (i.e., a portion overlapping the first semiconductor pattern SP1) of the i-th scan line SLi of the first group described above in FIG. 3B may be the first gate GE1 of the first transistor TR1. The first gate GE1 may overlap the first channel region AA1. In this embodiment, distal ends of the first gate GE1 may have different heights from a top surface of the first semiconductor pattern SP1. For example, an area overlapped with the second region A21 of the first gate insulating layer (i.e., the first insulating layer 10) may have a height higher than the other portions of the first gate GEL. A detailed description thereof will be given later.

In the process of doping the first semiconductor pattern SP1, the first gate GE1 may function as a self-aligned mask covering the first channel region AA1. The first gate GE1 may include molybdenum (Mo), an alloy containing molybdenum, titanium (Ti), an alloy containing titanium, or the like that have good heat resistance, but is not limited to thereto. The second insulating layer 20 may be disposed on the first insulating layer 10 and may cover the first gate GE1.

A shielding electrode BML may be disposed on the second insulating layer 20. The shielding electrode BML may be a conductive pattern. The shielding electrode BML may be a portion of the i-th scan line GLi of the second group described above with reference to FIG. 3B. The shielding electrode BML may include molybdenum (Mo), an alloy containing molybdenum, titanium (Ti), or an alloy containing titanium that have good heat resistance.

The shielding electrode BML may receive a bias voltage. The shielding electrode BML may receive the first power supply voltage ELVDD (see FIG. 3B). The shielding electrode BML may block an electrical potential due to a polarization phenomenon from affecting the second transistor TR2. In addition, the shielding electrode BML may block external light from reaching the second transistor TR2. Meanwhile, the shielding electrode BML may be a floating electrode isolated from other electrodes or lines.

Meanwhile, in an embodiment of the inventive concept, the display panel 100 may further include a shielding electrode disposed between the barrier layer 10br and the buffer layer 10bf. Alternatively, in an embodiment of the inventive concept, the shielding electrode may be omitted.

The third insulating layer 30 may be disposed on the second insulating layer 20. A second semiconductor pattern SP2 of the second transistor TR2 may be disposed on the third insulating layer 30. The second semiconductor pattern SP2 may include an oxide semiconductor. The second semiconductor pattern SP2 may include transparent conductive oxide (TCO) such as indium tin oxide (ITO), indium zinc oxide (IZO), indium gallium zinc oxide (IGZO), zinc oxide (ZnOx), and indium oxide (In₂O₃). The zinc oxide (ZnOx) may be zinc oxide (ZnO) and/or zinc peroxide (ZnO₂). The second transistor TR2 of FIG. 4A may correspond to the third and fourth transistors T3 and T4 described above with reference to FIG. 3B.

The oxide semiconductor may include a plurality of regions divided according to whether the transparent conductive oxide is reduced. A region in which the transparent conductive oxide is reduced (hereinafter referred to as a reduction region) has a higher conductivity than a region in which the transparent conductive oxide is not reduced (hereinafter referred to as a non-reduction region). The reduction region has a greater hydrogen concentration than the non-reduction region and substantially serves as the source/drain of the transistor or a signal line. The non-reduction region substantially corresponds to a second channel region AA2 of the second transistor TR2. That is, a partial region of the second semiconductor pattern SP2 may be the second channel region AA2 of the second transistor TR2, and other partial regions may be a second source region SA2 and a second drain region DA2 of the second transistor TR2, respectively. The second source region SA2 and the second drain region DA2 may respectively extend in opposite directions with the second channel region AA2 interposed therebetween. That is, the second channel region AA2 may be disposed between the second source region SA2 and the second drain region DA2.

The fourth insulating layer 40 may be disposed on the third insulating layer 30. The fourth insulating layer 40 may be may be referred to as a second gate insulating layer. The fourth insulating pattern 40 may overlap the second channel region AA2 of the second transistor TR2. In this embodiment, the fourth insulating layer 40 may include first to fourth regions A12, A22, A32, and A42. The second region A22 may be thicker than the other portions of the fourth insulating layer 40. The second portion A22 may be overlapped with the second semiconductor pattern SP2.

A second gate GE2 of the second transistor TR2 is disposed on the fourth insulating pattern 40. In this embodiment, distal ends of the second gate GE2 may have different heights from a top surface of the second semiconductor pattern SP2. For example, an area overlapped with the second region A22 of the second gate insulating layer (i.e., the fourth insulating pattern 40) may have a height higher than the other portions of the second gate GE2.

In this embodiment, the second transistor TR2 may include two gates. For example, when the second transistor TR2 corresponds to the third transistor T3 described above with reference to FIG. 3B, the shielding electrode BML and the second gate GE2 may correspond to the two gates G3-1 and G3-2 (see FIG. 3B) which are electrically connected to each other.

The fifth insulating layer 50 covering the fourth insulating pattern 40 and the second gate GE2 may be disposed on the fourth insulating layer 40. First to fourth connection electrodes CNE1, CNE2, CNE3, and CNE4 may be disposed on the fifth insulating layer 50.

The first connection electrode CNE1 may be connected to the first source region SA1 of the first transistor TR1 through a first contact hole CNT1 formed in the first to fifth insulating layers 10 to 50. The second connection electrode CNE2 may be connected to the first drain region DA1 of the first transistor TR1 through a second contact hole CNT2 form in the first to fifth insulating layers 10 to 50.

The third connection electrode CNE3 may be connected to the second source region SA2 of the second transistor TR2 through a third contact hole CNT3 formed in the fourth and fifth insulating layers 40 and 50. The fourth connection electrode CNE4 may be connected to the second drain region DA2 of the second transistor TR2 through a fourth contact hole CNT4 formed in the fourth and fifth insulating layers 40 and 50. Meanwhile, although not illustrated, the shielding electrode BML and the second gate GE2 may be electrically connected through a connection electrode disposed on the fifth insulating layer 50.

The first organic insulating layer 60 may be disposed on the fifth insulating layer 50, and the second organic insulating layer 70 may be disposed on the first organic insulating layer 60. In an embodiment, the second organic insulating layer 70 may be omitted. The first organic insulating layer 60 may cover the connection electrodes CNE1 to CNE4. The first organic insulating layer 60 may remove a step of the fifth insulating layer 50 disposed on a lower portion of the first organic insulating layer 60 and provide a flat top surface. Each of the first organic insulating layer 60 and the second organic insulating layer 70 may include a general-purpose polymer such as benzocyclobutene (BCB), polyimide, hexamethyldisiloxane (HMDSO), polymethylmethacrylate (PMMA), and polystyrene (PS), a polymer derivative having a phenolic group, an acrylic polymer, an imide-based polymer, an arylether-based polymer, an amide-based polymer, a fluorine-based polymer, a p-xylene-based polymer, a vinyl alcohol-based polymer, blends thereof, and the like.

The light emitting element LD may include an anode AE, a light emitting layer EML, and a cathode CE. The anode AE may be disposed on the second organic insulating layer 70. The anode AE may be a transparent electrode, a translucent electrode, or a reflective electrode. The anode AE may include a reflective layer constituted of Ag, Mg, Al, Pt, Pd, Au, Ni, Nd, Ir, Cr, or a compound thereof, and a transparent or translucent electrode layer provided on the reflective layer. The transparent or translucent electrode layer may include at least one selected from the group including indium tin oxide (ITO), indium zinc oxide (IZO), indium gallium zinc oxide (IGZO), zinc oxide (ZnO) or indium oxide (In₂O₃), and aluminum-doped zinc oxide (AZO). For example, the anode AE may include a three-layer structure of ITO/Ag/ITO but is not limited thereto.

A pixel defining film PDL may be disposed on the second organic insulating layer 70. The pixel defining film PDL may have a transparent property or a light absorbing property. For example, the pixel defining film PDL that absorbs light may include a black coloring agent. The black coloring agent may include a black dye or a black pigment. The black coloring agent may include carbon black, a metal such as chromium, or oxide thereof. The pixel defining film PDL may correspond to a shielding pattern having a light blocking characteristic.

The pixel defining film PDL may cover a portion of the anode AE. For example, an opening PDL-OP exposing a portion of the anode AE may be defined in the pixel defining film PDL. The pixel defining film PDL may increase a distance between an edge of the anode AE and the cathode CE. Accordingly, the pixel defining film PDL may serve to prevent an arc or the like from occurring at the edge of the anode AE.

Although not illustrated, a hole transport layer may be disposed between the anode AE and the light emitting layer EML. In addition, a hole injection layer may be disposed between the anode AE and the hole transport layer. An electron transport layer may be disposed between the light emitting layer EML and the cathode CE. An electron injection layer may be disposed between the electron transport layer and the cathode CE.

The encapsulation layer 140 may be disposed on the light emitting element layer 130. The encapsulation layer 140 may include an inorganic encapsulation layer 141, an organic encapsulation layer 142, and an inorganic encapsulation layer 143 that are sequentially laminated, but layers constituting the encapsulation layer 140 are not limited thereto.

The inorganic encapsulation layers 141 and 143 may protect the light emitting element layer 130 from moisture and oxygen, and the organic encapsulation layer 142 may protect the light emitting element layer 130 from foreign matter such as dust particles. The inorganic encapsulation layers 141 and 143 may include a silicon nitride layer, a silicon oxynitride layer, a silicon oxide layer, a titanium oxide layer, an aluminum oxide layer, or the like. The organic encapsulation layer 142 may include an acrylic organic layer but is not limited thereto.

FIG. 4B is an enlarged view of a portion of the display panel 100 (see FIG. 4A) in which the second transistor TR2 is disposed. The second transistor TR2 and the fourth insulating layer 40 will be described in more detail with reference to FIG. 4B. Descriptions of the second transistor TR2 and the fourth insulating layer 40 may be similarly applied to the first transistor TR1 and the first insulating layer 10 of FIG. 4A, respectively.

In this embodiment, the fourth insulating layer 40 may include the first region A12, the second region A22, the third region A32, and the fourth region A42.

The first region A12 may overlap the second source region SA2 and a partial region of the second gate GE2 which overlap the second semiconductor pattern SP2. In this case, the partial region of the second gate GE2 overlapping the first region A12 is defined as a ‘normal region G2a’. The first region A12 may include a first sub-region Ala overlapping the second source region SA2 and a second sub-region Alb overlapping the normal region G2a.

The fourth insulating layer 40 may provide an integral shape in the first sub-region Ala and the second sub-region Alb. In other words, the first region A12 of the fourth insulating layer 40 may extend from the region overlapping the second source region SA2 to the region overlapping the normal region G2a.

The second region A22 may overlap another partial region of the second gate GE2. In this case, the other partial region of the second gate GE2 overlapping the second region A22 is defined as a ‘protruding region G2b’. The third region A32 may overlap the second drain region D3 and may extend from the second region A22. The third region A32 may be spaced apart from the first region A12 with the second region A22 interposed therebetween.

In an embodiment of the inventive concept, a thickness t2 of the fourth insulating layer 40 in the second region A22 may be greater than a thickness t1 of the first region A12. A thickness t3 of the fourth insulating layer 40 in the third region A32 may be smaller than the thickness t2 in the second region A22. Accordingly, the fourth insulating layer 40 may include the second region A22 which has a thickness thicker than those of the first and third regions A12 and A32.

The fourth insulating layer 40 may extend at a constant thickness in the first region A12 and may have a flat top surface. The fourth insulating layer 40 may have a constant thickness in the third region A32 and may have a flat top surface. In an embodiment, the thickness t3 of the fourth insulating layer 40 in the third region A32 may be substantially the same as the thickness t1 in the first region A12.

In this embodiment, the fourth insulating layer 40 may have a constant thickness and a flat top surface in the second region A22. Accordingly, the second region A22 of the fourth insulating layer 40 may form a step together with each of the first region A12 and the third region A32.

A top surface of the fourth insulating layer 40 in the second region A22 may be disposed farther from a top surface of the second semiconductor pattern SP2 than the top surface of the fourth insulating layer 40 in the first region A12. The fourth insulating layer 40 may include a first step portion connecting the top surface in the first region A12 to the top surface in the second region A22 and a second step portion connecting the top surface in the second area A22 to a top surface in the third region A32. The top surface in the first region A12 and the top surface in the second region A22 may form a step, and the top surface in the third region A32 and the top surface in the second region A22 may form a step.

In an embodiment, a side surface of the first step portion may be perpendicular to each of the top surface in the first region A12 and the top surface in the second region A22, and a side surface of the second step portion may be perpendicular to each of the top surface in the second region A22 and the top surface in the third region A32.

The fourth region A42 may not overlap the second semiconductor pattern SP2 and may be a region of the fourth insulating layer 40 that is in contact with an insulating layer (i.e., the third insulating layer 30) disposed on a lower portion of the fourth insulating layer 40. In this embodiment, the fourth region A42 may be a region of the fourth insulating layer 40 other than the first to third regions A12, A22, and A32.

The second gate GE2 may be disposed on the fourth insulating layer 40 and may overlap the second channel region AA2. As described above, the second gate GE2 may include the normal region G2a and the protruding region G2b.

A top surface u2 of the protruding region G2b may be disposed higher than a top surface u1 of the normal region G2a. In this embodiment, each of the normal region G2a and the protruding region G2b may have a constant thickness. The normal region G2a and the protruding region G2b may form a step. In this case, the shape of the step formed by the normal region G2a and the protruding region G2b may correspond to the shape of the step formed by the first region A12 and the second region A22 of the fourth insulating layer 40.

An edge e1 (hereinafter referred to as a first edge e1) of the normal region G2a spaced apart from the protruding region G2b may be closer to the second source region SA2 than the protruding region G2b, and an edge e2 (hereinafter referred to as a second edge e2) of the protruding region G2b spaced apart from the normal region G2a may be closer to the second drain region DA2 than the normal region G2a. In an embodiment of the inventive concept, a distance d2 from the second semiconductor pattern SP2 to the second edge e2 may be longer than a distance d1 from the second semiconductor pattern SP2 to the first edge e1. In an embodiment, the second edge e2 of the second gate GE2 may be substantially aligned with the second region A22 of the second gate insulating layer (i.e., the fourth insulating layer 40) having a thickness thicker than the other portions of the second gate insulating layer (i.e., the fourth insulating layer 40).

A width of the second channel region AA2 of the second transistor TR2 may be reduced in a high-resolution display panel 100 (see FIG. 4A), so that a Short Channel Effect (SCE) may cause a Drain Induced Barrier Lowering (DIBL) phenomenon and a Hot Carrier Effect (HCE) may occur. When the DIBL phenomenon occurs, there may occur a problem that a leakage current is increased even when an on-state gate voltage is not applied. When the hot carrier effect occurs, there may occur a problem that the reliability of an insulation property is reduced due to a carrier trap in the fourth insulating layer 40.

According to an embodiment of the inventive concept, however, by allowing a portion of the insulating layer disposed in a partial region of a region overlapping the second channel region AA2 adjacent to the second drain region DA2 to be provided thicker, an electric field generated in a portion of the second channel region AA2 adjacent to the second drain region DA2 may be reduced. Thus, in the high resolution display panel 100, by preventing the DIBL phenomenon from occurring, it is possible to prevent an increase in leakage current in the channel region and reduce the hot carrier effect by securing the reliability of insulation characteristics.

Accordingly, the characteristics of the second transistor TR2 included in the high-resolution display panel 100 (see FIG. 4A) may be improved, thereby improving the operational reliability of the display panel 100 (see FIG. 4A).

In addition, according to an embodiment of the inventive concept, by allowing a portion of the insulating layer disposed between the second channel region AA2 and the second gate GE2 to be provided thicker, it is possible to reduce the occurrence of a tunneling phenomenon due to the break-down of the fourth insulating layer 40. Accordingly, it is possible to prevent a decrease in threshold voltage and an increase in leakage current crossing the insulating layer due to the tunneling phenomenon. In addition, by preventing band-to-band tunneling from occurring between a gate region and the drain region when a difference between a gate voltage and a drain voltage is large, an increase in leakage current due to a Gate Induced Drain Leakage (GIDL) phenomenon may be prevented.

According to an embodiment, when viewed in a direction perpendicular to an extension direction of the second source region SA2, the second channel region AA2, and the second drain region DA2, a length L_{E} of the second region A22 in the extension direction may be smaller than or equal to ½ of a length Lc of the second channel region AA2 in the extension direction. When the length L_{E} of the second region A22 in the extension direction is greater than ½ of the length Lc of the second channel region AA2 in the extension direction, a change in the electric field in the second channel region AA2 due to a change in the thickness of the fourth insulating layer 40 may affect a voltage between the second gate GE2 and the second source region SA2. Accordingly, by disposing the second region A22 in a region of the second channel region AA2 closer to the second drain region DA2 than to the second source region SA2, it is possible to prevent an increase in leakage current due to phenomena occurring between the second gate GE2 and the second drain region DA2 and, at the same time, to minimize the effect on the voltage between the second gate GE2 and the second source region SA2 caused by change in the electric field.

According to an embodiment, the thickness t2 of the fourth insulating layer 40 in the second region A22 may be smaller than or equal to twice the thickness t1 in the first region A12. Because the amount of change in the threshold voltage increases as the thickness of the fourth insulating layer 40 increases, the changed threshold voltage may be out of the driving range of the second transistor TR2 in the display panel 100 (see FIG. 4A) when the thickness t2 of the fourth insulating layer 40 in the second region A22 is greater than twice the thickness t1 in the first region A12. However, an embodiment of the inventive concept is not necessarily limited thereto and may vary depending on the size or use of the second transistor TR2.

The above description of the first to fourth regions A12, A22, A32, and A42 of the fourth insulating layer 40 may be equally applied to the first to fourth regions A11, A21, A31, and A41 of the first insulating layer 10 of FIG. 4A, respectively, and the above description of the second gate GE2 may be equally applied to the first gate GE1 of FIG. 4A.

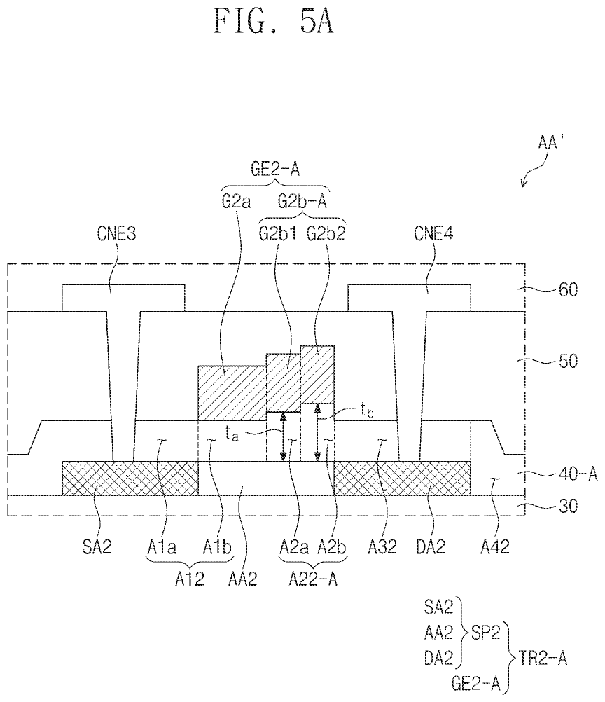

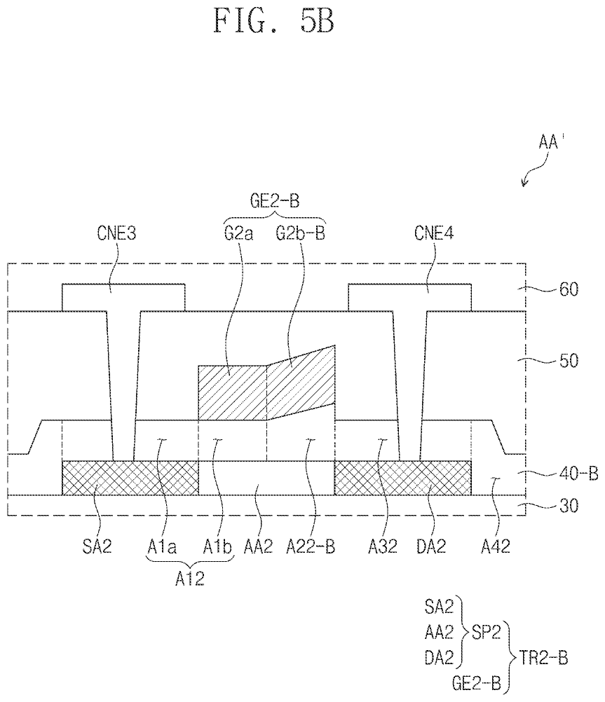

FIG. 5A and FIG. 5B are enlarged cross-sectional views of transistors in an area corresponding to the area AA′ of FIG. 4A, according to embodiments of the inventive concept. The same/similar reference numerals are used for components the same as/similar to those described with reference to FIG. 1 to FIG. 4B, and a duplicate description will not be given.

Referring to FIG. 5A, a fourth insulating layer 40-A according to this embodiment may include a first region A12, a second region A22-A, a third region A32, and a fourth region A42. As the description of the first region A12, the third region A32, and the fourth region A42 given above with reference to FIG. 4B may be similarly applied to the first region A12, the third region A32, and the fourth region A42 in FIG. 5A, the second region A22-A having a difference will be described in detail.

In this embodiment, the second region A22-A may include a first sub-region A2a and a second sub-region A2b. The first sub-region A2a may be a region extending from the first region A12, and the second sub-region A2b may be a region extending from the third region A32 to the first sub-region A2a.

The fourth insulating layer 40-A may have a constant first thickness ta in the first sub-region A2a and a constant second thickness tb in the second sub-region A2b. The second thickness tb may be greater than the first thickness ta. Accordingly, the first sub-region A2a of the fourth insulating layer 40-A may form a step together with the first region A12, and the second sub-region A2b may form a step together with each of the first sub-region A2a and the third region A32. The fourth insulating layer 40-A may have a thickness thicker than the other regions, for example, the first and third regions A12 and A32, in the second region A22-A. The surface of the fourth insulating layer 40-A have a step shape.

In an embodiment, the fourth insulating layer 40-A may include a first step portion connecting a top surface in the first region A12 and a top surface in the first sub-region A2a, a second step portion connecting the top surface in the first sub-region A2a and a top surface in the second sub-region A2b, and a third step portion connecting the top surface in the second sub-region A2b and a top surface in the third region A32.

Although illustrated as an example to include two sub-regions A2a and A2b in FIG. 5A, the second region A22-A may include three or more sub-regions having sequentially increasing thicknesses.

In this embodiment, a second gate GE2-A may include a normal region G2a and a protruding region G2b-A, and the protruding region G2b-A may include a first sub-protruding region G2bl and a second sub-protruding region G2b2. A top surface of the first sub-protruding region G2bl may be disposed higher from a top surface of a second semiconductor pattern SP2 than a top surface of the normal region G2a and a top surface of a second sub-protruding region G2b2 may be disposed higher from the top surface of the second semiconductor pattern SP2 than the top surface of the first sub-protruding region G2bl. The shape of steps formed between the normal region G2a and the first sub-protruding region G2b1 and between the first and second sub-protruding regions G2bl and G2b2 may correspond to the shape of the steps formed by the top surface of the fourth insulating layer 40-A. Accordingly, in this embodiment, the protruding region G2b-A of the second gate GE2 may have a stepped shape.

According to this embodiment, the second region A22-A includes the plurality of sub-regions A2a and A2b whose thicknesses become sequentially thicker as distances from the sub-regions A2a and A2b to the second drain region DA2 become sequentially shorter, so that the degree of change in an electric field in a second channel region AA2 may be reduced. Accordingly, a transistor TR2-A having improved electrical reliability may be provided because a rapid change in the electric field in the second channel region AA2 may be prevented.

Referring to FIG. 5B, a fourth insulating layer 40-B according to this embodiment may include a first region A12, a second region A22-B, a third region A32, and a fourth region A42. As the description of the first region A12, the third region A32, and the fourth region A42 given above with reference to FIG. 4B may be similarly applied to the first region A12, the third region A32, and the fourth region A42 in FIG. 5B, the second region A22-B having a difference will be described in detail.

In this embodiment, the fourth insulating layer 40-B may become gradually thicker as a distance in an extension direction of a second drain region DA2 between a point in the second region A22-B and the second drain region DA2 becomes shorter. In other words, the thickness of the fourth insulating layer 40-B may gradually increase as a point in the second region A22-B moves from the first region A12 to the third region A32.

A top surface of the fourth insulating layer 40-B in the second region A22-B may have an inclined surface extending from a top surface of the first region A12. The second region A22-B of the fourth insulating layer 40-B may form a step together with the third area A32. The fourth insulating layer 40-B may include a step portion connecting the inclined top surface in the second region A22-B and a top surface in the third area A32.

In this embodiment, a second gate GE2-B may include a normal region G2a and a protruding region G2b-B. A top surface of the protruding region G2b-B may extend from a top surface of the normal region G2a and may provide an inclination corresponding to the inclined top surface of the fourth insulating layer 40-B.

According to this embodiment, the second region A22-B gradually becomes thicker as a point in the second region A22-B approaches the second drain area DA2, so that the degree of change in an electric field may be minimized. Accordingly, a transistor TR2-B having improved electrical reliability may be provided because the transistor TR2-B may not include, in a second channel region AA2, a portion in which the electric field rapidly changes.

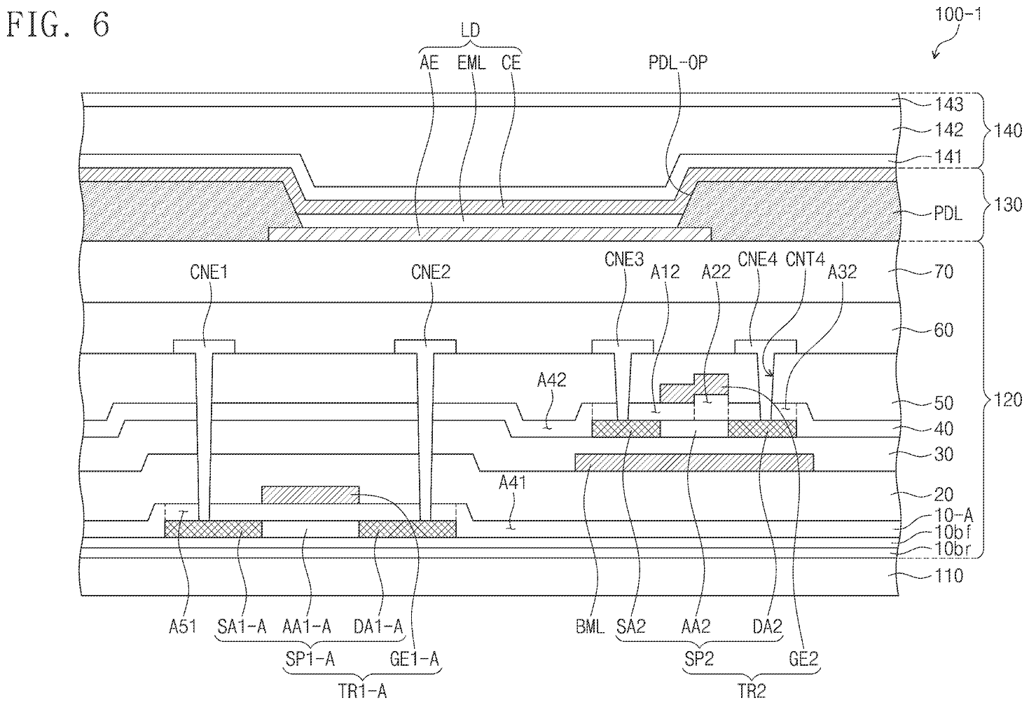

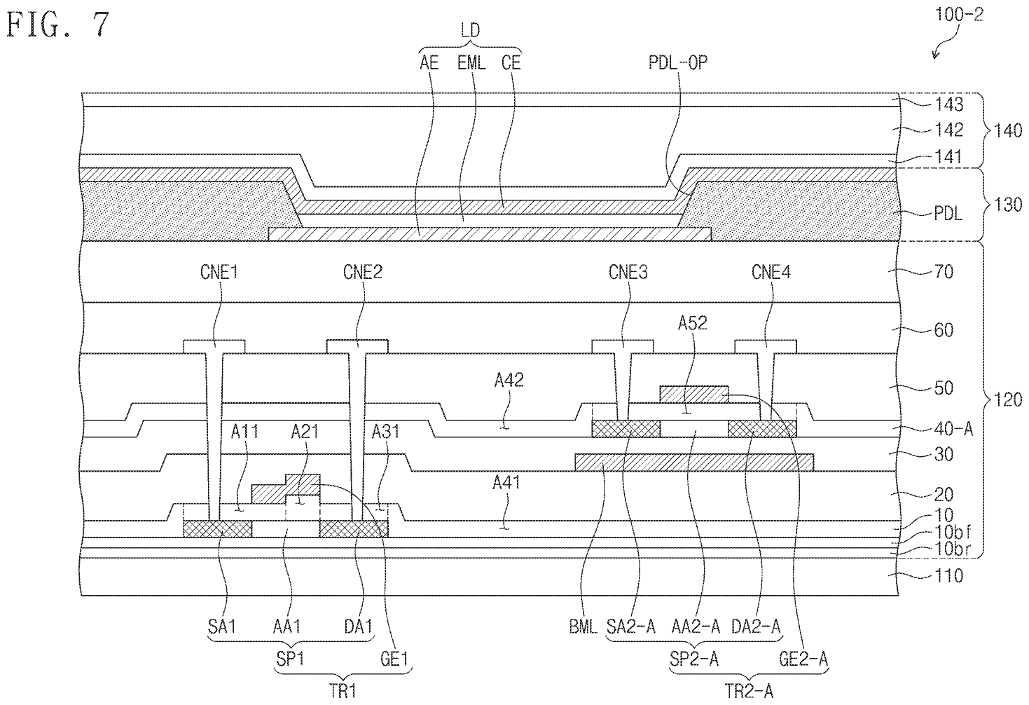

FIG. 6 is a cross-sectional view of a display panel according to an embodiment of the inventive concept. FIG. 6 illustrates a first transistor TR1-A (‘second transistor’ in the claim) as an example of silicon transistors, and a second transistor TR2 (‘first transistor’ in the claim) as an example of oxide transistors. Descriptions of a second semiconductor pattern SP2 (‘first semiconductor pattern’ in the claim), a second gate GE2 (‘first gate’ in the claim) included in the second transistor TR2, a second source region SA2 (‘first source region’ in the claims) included in the second semiconductor pattern SP2, a second drain region DA2 (‘first drain region’ in the claims) included therein, and a second channel region AA2 (‘first channel region’ in the claims) included therein, and a fourth insulating layer 40 (‘first insulating layer’ in the claim) will not be given below because the descriptions of the corresponding components given above with reference to FIG. 4A and FIG. 4B may be equally applied.

The first transistor TR1-A includes a first semiconductor pattern SP1-A (‘second semiconductor pattern’ in the claims) disposed between the buffer layer 10bf and a first insulating layer 10-A (‘lower insulating layer’ in the claims) and a first gate GE1-A (‘second gate’ in the claims) disposed between the first and second insulating layers 10A and 20. The first semiconductor pattern SP1-A includes a first source region SA1-A (‘second source region’ in the claims), a first drain region DA1-A (‘second drain region’ in the claims), and a first channel region AA1-A (‘second channel region’ in the claims).

In the present embodiment, the first insulating layer 10-A may include fourth and fifth regions A41 and A51. The fourth region A41 may be in contact with the buffer layer 10bf, and the fifth region A51 may overlap the first semiconductor pattern SP1-A. The first insulating layer 10-A may have a fixed thickness in the fifth region A51. That is, the first insulating layer 10-A may have a uniform thickness on the buffer layer 10bf in a region overlapping the first semiconductor pattern SP1-A. Accordingly, the first gate GE1-A may also be provided in a generally flat form without having a protruding portion (or stepped portion).

In the present embodiment, the first transistor TR1-A of FIG. 6 may correspond to at least one of the first, second, and fifth to seventh transistors T1, T2, and T5 to T7 of FIG. 3B. For example, the first transistor TR1-A may correspond to the first transistor T1 of FIG. 3B. Here, with regard to the other transistors (i.e., second and fifth to seventh transistors T2 and T5 to T7) of FIG. 3B, the same descriptions as provided above with respect to the first transistor TR1 of FIG. 4A may be applied.

According to an embodiment, in order to implement a high-resolution display panel 100-1, a size of a switching transistor for transferring on/off signals and sizes of initialization transistors for transferring a voltage of a certain value (e.g., the first power supply voltage ELVDD, second power supply voltage ELVSS, first initialization voltage Vint, or second initialization voltage VAint described above with reference to FIG. 3B) according to a received on/off signal may be reduced. That is, a short channel effect may occur due to reduction in sizes of the second to seventh transistors T2 to T7 (see FIG. 6) of FIG. 3B.

Meanwhile, considering that a magnitude of a driving current is directly related to intensity of light emitted by the light emitting element LD, and moreover directly affects image quality of the display panel 100-1, a driving transistor for transferring the driving current to the light emitting element LD may be designed to maintain at least a certain size. That is, since the first transistor T1 of FIG. 3B has at least the certain size, the short channel effect may not occur.

Here, the first transistor TR1 of FIG. 4A may be applied to the second and fifth to seventh transistors T2 and T5 to T7 of FIG. 3B, in which the short channel effect occurs, among silicon transistors, and the first transistor TR1-A of FIG. 6 may be applied to the first transistor T1 of FIG. 3B, in which the short channel effect does not occur.

However, an embodiment of the inventive concept is not limited thereto, and in the case of the display panel 100-1 including a silicon transistor in which the short channel effect does not occur among the silicon transistors, the first transistor TR1-A of FIG. 6 may be applied to the silicon transistor in which the short channel effect does not occur regardless of the type of the transistor. Here, the first transistor TR1 of FIG. 4A may be applied to a silicon transistor in which the short channel effect occurs.

FIG. 7 is a cross-sectional view of a display panel according to an embodiment of the inventive concept. FIG. 7 illustrates an example of the first transistor TR1 among silicon transistors and an example of the second transistor TR2-A among oxide transistors. The same descriptions as provided above with reference to FIGS. 4A and 4B may be applied to the first transistor TR1, and thus descriptions thereof are not provided below.

The second transistor TR2-A includes a second semiconductor pattern SP2-A disposed between third and fourth insulating layers 30 and 40-A and a second gate GE2-A disposed between fourth and fifth insulating layers 40-A and 50. The second semiconductor pattern SP2-A includes a second source region SA2-A, a second drain region DA2-A, and a second channel region AA2-A.

In the present embodiment, the fourth insulating layer 40-A (‘upper insulating layer’ in the claims) may include fourth and fifth regions A42 and A52. The fourth region A42 may be in contact with the third insulating layer 30, and the fifth region A52 may overlap the second semiconductor pattern SP2-A. The fourth insulating layer 40-A may have a uniform thickness in the fifth region A52. That is, the fourth insulating layer 40-A may have a same thickness in a region overlapping the second semiconductor pattern SP2-A. Accordingly, the second gate GE2-A may also be provided in a generally flat form without having a stepped portion.

In the present embodiment, the second transistor TR2-A of FIG. 7 may correspond to at least one of the third and fourth transistors T3 and T4 of FIG. 3B. In the case of a display panel including an oxide transistor in which the short channel effect does not occur among oxide transistors, the second transistor TR2-A of FIG. 7 may be applied to the oxide transistor in which the short channel effect does not occur regardless of the type of the transistor. Here, the second transistor TR2 of FIG. 4A may be applied to an oxide transistor in which the short channel effect occurs.

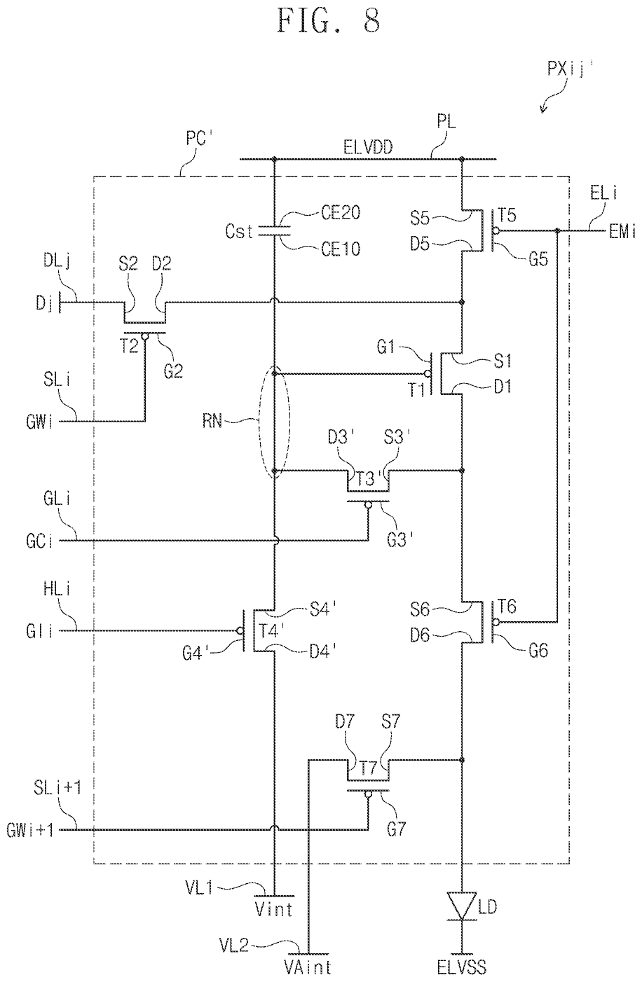

FIG. 8 is an equivalent circuit diagram of a pixel according to an embodiment of the inventive concept.

Referring to FIG. 8, a pixel PXij′ according to the present embodiment may include a pixel circuit PC′ and a light emitting element LD. The pixel circuit PC′ may include first to seventh transistors T1, T2, T3′, T4′, T5, T6, and T7 and a capacitor Cst. In present embodiment, the first to seventh transistors T1, T2, T3′, T4′, T5, T6, and T7 may all be P-type transistors. The first to seventh transistors T1, T2, T3′, T4′, T5, T6, and T7 may all be silicon transistors. For example, each of the first to seventh transistors T1, T2, T3′, T4′, T5, T6, and T7 may be a transistor having a semiconductor layer including low-temperature polycrystalline silicon (LTPS). However, an embodiment of the inventive concept is not limited thereto, and the first to seventh transistors T1, T2, T3′, T4′, T5, T6, and T7 may all be N-type transistors. Alternatively, the first to seventh transistors T1, T2, T3′, T4′, T5, T6, and T7 may all be oxide transistors.

Since the descriptions provided above with reference to FIG. 3B may be similarly applied to the first, second, and fifth to seventh transistors T1, T2, and T5 to T7, the third and fourth transistors T3′ and T4′ are described in detail below.

In the present embodiment, a drain D3′ of the third transistor T3′ may be electrically connected to the reference node RN, and a source S3′ of the third transistor T3′ may be electrically connected to the drain D1 of the first transistor T1. A gate G3′ of the third transistor T3′ may be electrically connected to the i-th scan line GLi of the second group. The third transistor T3′ is illustrated as including one gate, but is not limited thereto, and may also include a plurality of gates as described above with reference to FIG. 3B.

In the present embodiment, a drain D4′ of the fourth transistor T4′ may be electrically connected to the second voltage line VL1, and a source S4′ of the fourth transistor T4′ may be electrically connected to the reference node RN. A gate G4′ of the fourth transistor T4′ may be electrically connected to the i-th scan line HLi of the third group. The fourth transistor T4′ is illustrated as including one gate, but is not limited thereto, and may also include a plurality of gates as described above with reference to FIG. 3B.

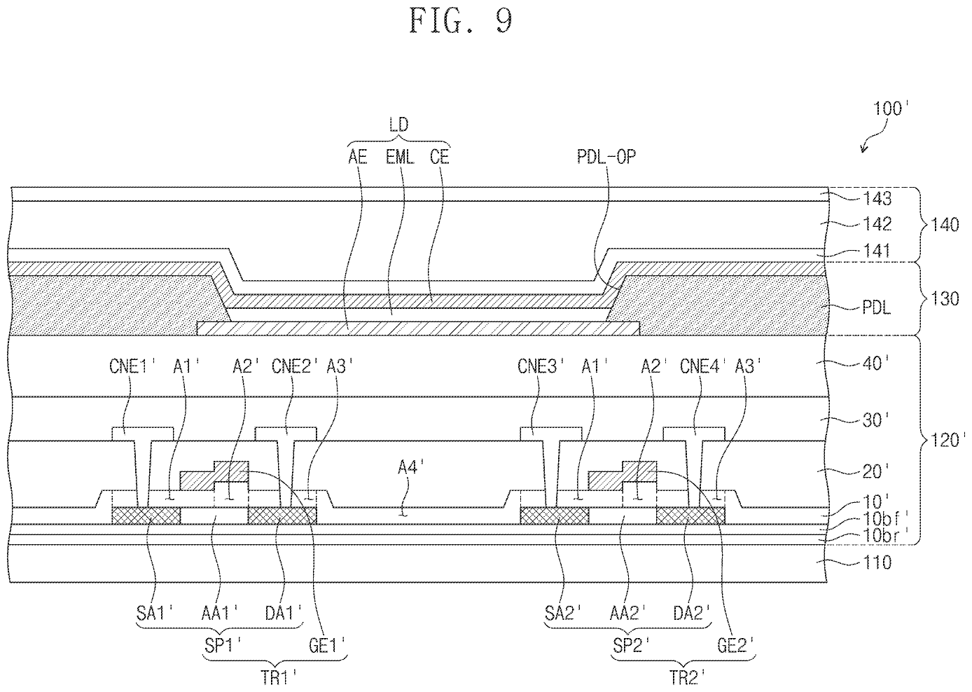

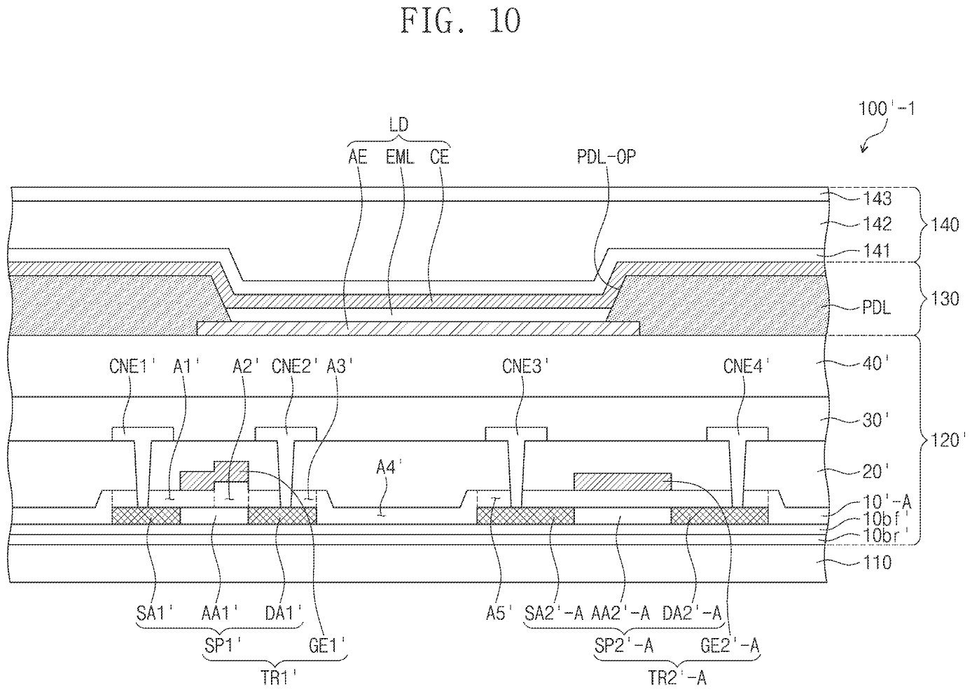

FIG. 9 is a cross-sectional view of a display panel according to an embodiment of the inventive concept.

Referring to FIG. 9, a display panel 100′ according to the present embodiment may include the pixel PXij′ having the equivalent circuit illustrated in FIG. 8. The display panel 100′ may include the base layer 110, a circuit layer 120′, the light emitting element layer 130, and the encapsulation layer 140. Since the descriptions provided above with reference to FIG. 4A may be similarly applied to the base layer 110, the light emitting element layer 130, and the encapsulation layer 140, the circuit layer 120′ is described in detail below.

In the present embodiment, the circuit layer 120′ may include a barrier layer 10br′, a buffer layer 10bf′, first and second insulating layers 10′ and 20′, first and second organic insulating layers 30′ and 40′, first and second transistors TR1′ and TR2′, and connection electrodes CNE1′, CNE2′, CNE3′, and CNE4′. The barrier layer 10br′, the buffer layer 10bf′, the first and second insulating layers 10′ and 20′, and the first and second organic insulating layers 30′ and 40′ may be sequentially arranged on the base layer 110 in the third direction DR3.

The first and second transistors TR1′ and TR2′ of FIG. 9 are illustrated as examples of two of the first to seventh transistors T1, T2, T3′, T4′, T5, T6, and T7 (see FIG. 8) of FIG. 8.

In the present embodiment, the first and second transistors TR1′ and TR2′ may be arranged on the same layer. A first semiconductor pattern SP1′ of the first transistor TR1′ and a second semiconductor pattern SP2′ of the second transistor TR2′ may be arranged on the buffer layer 10bf′.

The first insulating layer 10′ may be arranged on the buffer layer 10bf′ and may cover the first and second semiconductor patterns SP1′ and SP2′. In the present embodiment, the first insulating layer 10′ may include first to fourth regions A1′ to A4′. The first to third regions A1′ to A3′ may be arranged in a region overlapping the first semiconductor pattern SP1′ of the first transistor TR1′ and a region overlapping the second semiconductor pattern SP2′ of the second transistor TR2′, and the fourth region A4′ may be a region other than the first to third regions A1′ to A3′ and may be a region, which is in contact with the buffer layer 10bf′, in the first insulating layer 10′.

The first region A1′ may overlap a first source region SA1′ of the first transistor TR1′ and a portion of a first channel region AA1′ adjacent to the first source region SA1′. The second region A2′ may overlap another portion of the first channel region AA1′ disposed adjacent to a first drain region DA1′ of the first transistor TR1′, and the third region A3′ may overlap the first drain region DA1′ of the first transistor TR1′. The second region A2′ may have a larger thickness than the first region A1′ and the third region A3′.

The first insulating layer 10′ may be designed to have a relatively large thickness in the second region A2′ disposed adjacent to the first drain region DA1′ so as to prevent occurrence of a tunneling phenomenon and GIDL phenomenon that may occur between the first gate GE1′ and the first channel region AA1′ and reduce a hot carrier effect and DIBL phenomenon due to the short channel effect. Accordingly, when implementing the high-resolution display panel 100′, the transistors TR1′ and TR2′ having improved operational reliability may be provided.

Descriptions about the first to third regions A1′ to A3′ may be similarly applied to a region overlapping the second semiconductor pattern SP2′ of the second transistor TR2′, and with regard to other detailed descriptions about the first to third regions A1′ to A3′, the descriptions provided above with reference to FIGS. 4A to 5B may be similarly applied.

The first gate GE1′ of the first transistor TR1′ and the second gate GE2′ of the second transistor TR2′ may be arranged on the first insulating layer 10′. In the present embodiment, each of the first and second gates GE1′ and GE2′ may have a shape, two ends of which have different heights from the first and second semiconductor patterns SP1′ and SP2′. With regard to detailed descriptions about the first and second gates GE1′ and GE2′, the descriptions provided above with reference to FIGS. 4A to 5B may be similarly applied.

The second insulating layer 20′ may be arranged on the first insulating layer 10′ and may cover the first and second gates GE1′ and GE2′ The first to fourth connection electrodes CNE1′ to CNE4′ may be arranged on the second insulating layer 20′. The first and third connection electrodes CNE1′ and CNE3′ may be respectively connected to the first and second source regions SA1′ and SA2′ through contact holes formed in the first and second insulating layers 10′ and 20′. The second and fourth connection electrodes CNE2′ and CNE4′ may be respectively connected to the first and second drain regions DA1′ and DA2′ through contact holes formed in the first and second insulating layers 10′ and 20′.

The first organic insulating layer 30′ may be arranged on the second insulating layer 20′ and may cover the first to fourth connection electrodes CNE1′ to CNE4′. The second organic insulating layer 40′ may be arranged on the first organic insulating layer 30′.

FIG. 10 is a cross-sectional view of a display panel according to an embodiment of the inventive concept.

Referring to FIG. 10, a first insulating layer 10′-A according to the present embodiment may include first to fifth regions A1′ to A5′. The first to third regions A1′ to A3′ may be arranged in a region overlapping the first semiconductor pattern SP1′ of the first transistor TR1′, and the fifth region A5′ may be arranged in a region overlapping a second semiconductor pattern SP2′-A of a second transistor TR2′-A. The fourth region A4′ may be a region other than the first to third regions A1′ to A3′ and the fifth region A5′ and may be a region which is in contact with the buffer layer 10bf′.

The first insulating layer 10′-A may have a uniform thickness in a region overlapping the second semiconductor pattern SP2′-A. A second gate GE2′-A may be generally flat without having a stepped portion.

In the present embodiment, the first transistor TR1′ of FIG. 10 may correspond to any one of the second to seventh transistors T2, T3′, T4′, T5, T6, and T7 of FIG. 8, and the second transistor TR2′-A of FIG. 10 may correspond to the first transistor T1 of FIG. 8. However, an embodiment of the inventive concept is not limited thereto, and the first transistor TR1′ of FIG. 10 may correspond to transistors affected by the short channel effect among the first to seventh transistors T1, T2, T3′, T4′, T5, T6, and T7 of FIG. 8, and the second transistor TR2′-A of FIG. 10 may correspond to transistors not affected by the short channel effect among the first to seventh transistors T1, T2, T3′, T4′, T5, T6, and T7 of FIG. 8.

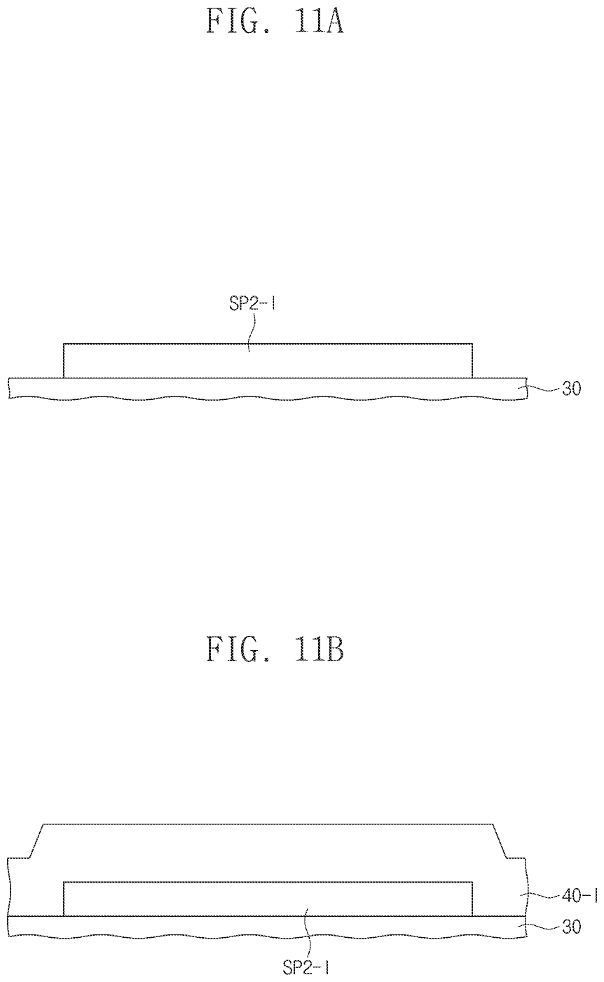

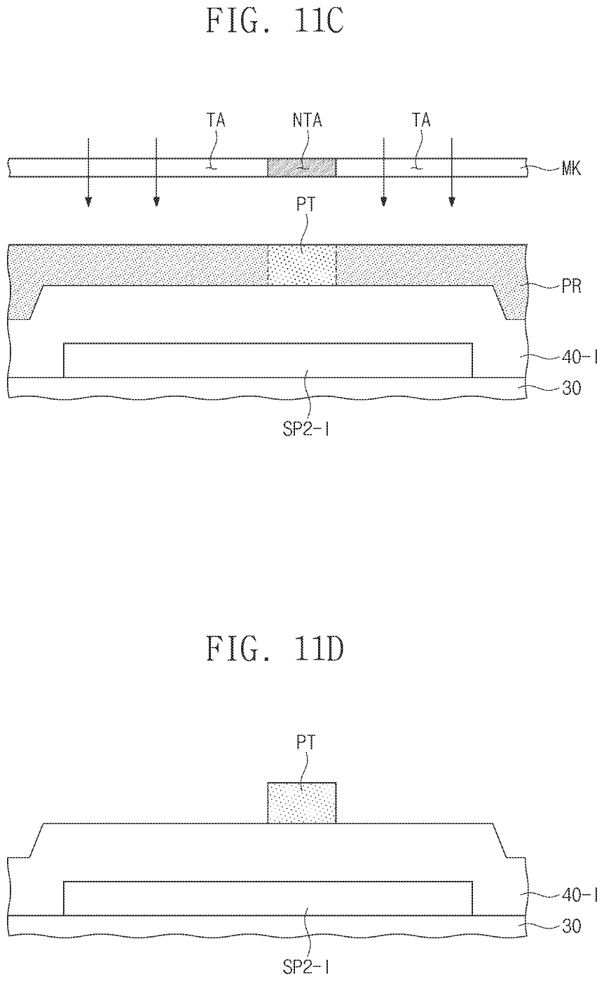

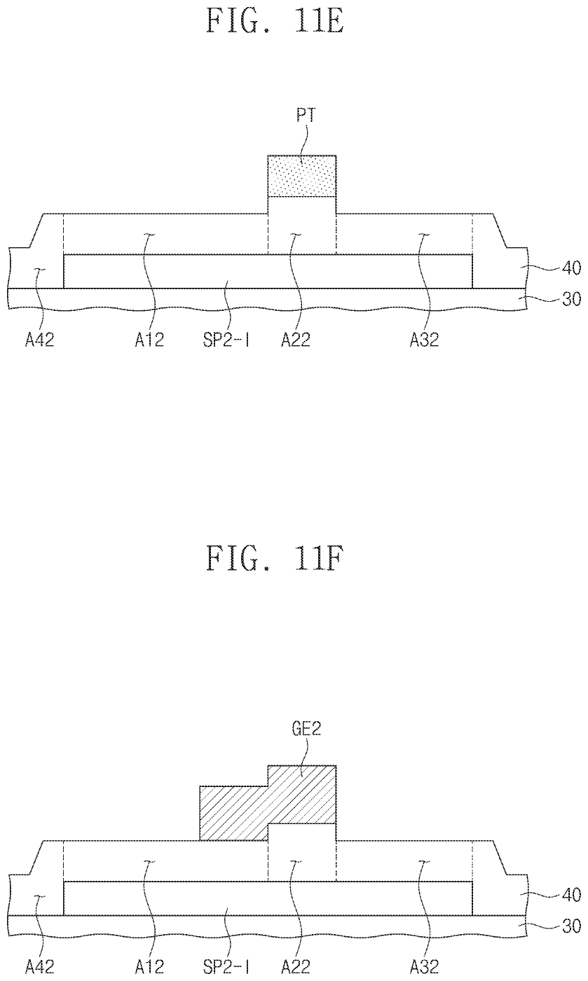

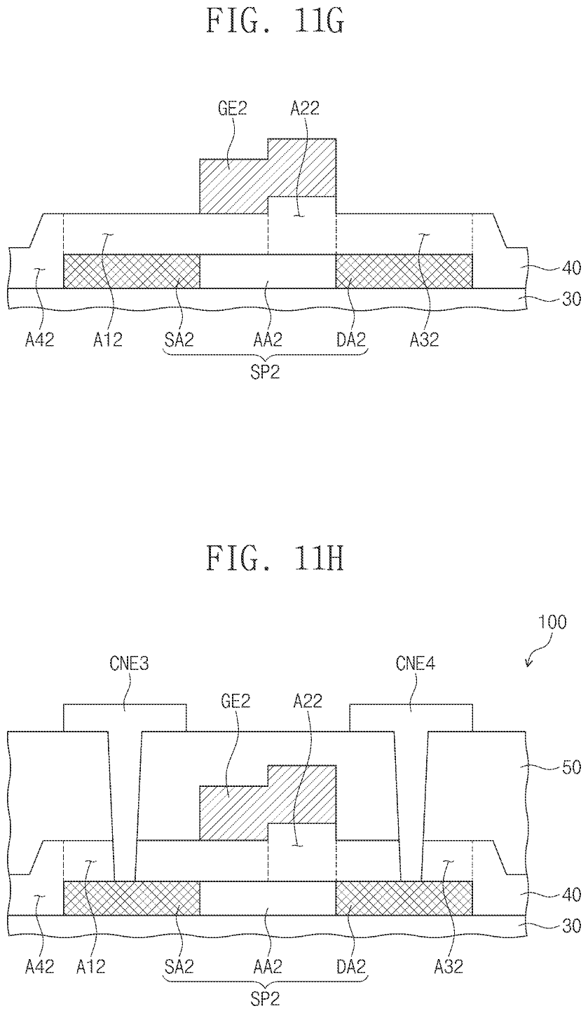

FIGS. 11A to 11H are cross-sectional views illustrating a method of manufacturing a display panel according to an embodiment of the inventive concept.

A display panel manufacturing method of the inventive concept includes forming a preliminary semiconductor pattern on a base layer, forming a first preliminary insulating layer on the preliminary semiconductor pattern, forming a first insulating layer including a first region and a second region having a larger thickness than the first region through a photolithography process, forming a gate overlapping a portion of the first region and the second region on the first insulating layer, and forming, from the preliminary semiconductor pattern, a semiconductor pattern including a channel region overlapping the gate and a source region and a drain region which extend in opposite directions with the channel region therebetween.

The processes illustrated in FIGS. 11A to 11H may correspond to processes of a method of manufacturing some elements of the display panel 100 (see FIG. 11H) including the second transistor TR2 illustrated in FIG. 4B. Hereinafter, a display panel manufacturing method will be described with a focus on a method of forming the second transistor TR2 of FIG. 4B, but descriptions about the method may be similarly applied to the first transistor TR1 of FIG. 4A and the first and second transistors TR1′ and TR2′ of FIG. 9.

As illustrated in FIG. 11A, a preliminary semiconductor pattern SP2-I may be formed on the base layer 110 (see FIG. 4A). In the present embodiment, the preliminary semiconductor pattern SP2-I may include an oxide semiconductor material, and may be formed by depositing an oxide semiconductor material on the third insulating layer 30 arranged on the base layer 110 (see FIG. 4A). However, an embodiment of the inventive concept is not limited thereto, and, when forming a silicon transistor, the preliminary semiconductor pattern SP2-I may include a silicon semiconductor material.

Thereafter, as illustrated in FIG. 11B, a preliminary insulating layer 40-I may be formed on the preliminary semiconductor pattern SP2-I. The preliminary insulating layer 40-I may include an inorganic material. For example, the preliminary insulating layer 40 may include at least one of silicon oxide, silicon nitride, or silicon oxynitride. The preliminary insulating layer 40-I may be formed through a PECVD process.

Thereafter, as illustrated in FIGS. 11C to 11E, an insulating layer 40 including first to fourth regions A12, A22, A43, and A42 may be formed. The thickness-controlled insulating layer 40 may be formed by differently setting a degree of etching of the preliminary insulating layer 40-I for each region of the preliminary insulating layer 40-I through a photolithography process.

As illustrated in FIG. 11C, a photoresist layer PR may be formed on the preliminary insulating layer 40-I, and a mask MK including a transmissive region TA and a non-transmissive region NTA may be provided on the photoresist layer PR. An exposure process for providing light on the mask MK may be performed, wherein a portion of the photoresist layer PR corresponding to the transmissive region TA may be irradiated with a larger amount of light than another portion of the photoresist PR corresponding to the non-transmissive region NTA.

After the exposure process, a developing process may be performed to provide a developing solution on the photoresist layer PR irradiated with light. Due to the developing solution, a portion of the photoresist layer PR overlapping the non-transmissive region NTA may remain, and another portion of the photoresist layer PR corresponding to the transmissive region TA may be removed. Accordingly, as illustrated in FIG. 11D, the photoresist layer PR may be formed as a pattern PT (hereinafter referred to as a photoresist pattern).

As illustrated in FIG. 11E, after the developing process, the preliminary insulating layer 40-I exposed by the photoresist pattern PT may be partially removed in a thickness direction through an etching process, thus forming the insulating layer 40 including the first to fourth regions A12, A22, A32, and A42. The first to third regions A12, A22, and A32 may be regions corresponding to a region overlapping the preliminary semiconductor pattern SP2-I, and the fourth region A42 may be a region not overlapping the preliminary semiconductor pattern SP2-I. The second region A22 may be a region which overlaps the photoresist pattern PT and has a relatively large thickness, and the first and third regions A12 and A32 may be regions which extend in opposite directions from the second region A22.

Although FIG. 11E illustrates that the insulating layer 40 having a fixed thickness is formed in the second region A22, an embodiment of the inventive concept is not limited thereto, and the insulating layer 40 may be formed in a stepped form as illustrated in FIG. 5A or in an inclined form as illustrated in FIG. 5B by controlling the thickness of the photoresist pattern PT for each region by differently setting an amount of light provided during the exposure process.

Meanwhile, although the above descriptions related to FIGS. 11C to 11E are provided based on a positive photo process in which a pattern is formed in correspondence with the non-transmissive region NTA of the mask MK, an embodiment of the inventive concept is not limited thereto, and the thickness-controlled insulating layer 40 may be formed through a negative photo process in which a pattern is formed in correspondence with the transmissive region TA of the mask MK.

Thereafter, as illustrated in FIG. 11F, a gate GE2 may be formed on the insulating layer 40. The gate GE2 may be formed to overlap a portion of the first region A12 and the second region A22 of the insulating layer 40. In detail, the gate GE2 may be arranged to overlap a region corresponding to a channel region AA2 (see FIG. 11G) of the preliminary semiconductor pattern SP2-1.

Thereafter, as illustrated in FIG. 11G, a semiconductor patter SP2 may be formed from the preliminary semiconductor pattern SP2-I, the semiconductor pattern SP2 including the channel region AA2 and a source region SA2 and a drain region DA2 which extend in opposite directions with the channel region AA2 therebetween. A portion of the preliminary semiconductor pattern SP2-I exposed from the gate GE2 may be doped by providing a dopant on the preliminary semiconductor pattern SP2-I.

The channel region AA2 not doped with the dopant may be formed in a region overlapping the gate GE2, and the source region SA2 and drain region DA2 doped with the dopant may be formed in a region not overlapping the gate GE2.

Thereafter, as illustrated in FIG. 11H, an insulating layer 50 and connection electrodes CNE3 and CNE4 may be additionally formed on the insulating layer 40 and the gate GE2. The display panel 100 according to an embodiment of the inventive concept may be manufactured through a process of forming other insulating layers and a light emitting element.

According to an embodiment of the inventive concept, by increasing the thickness of the gate insulating layer disposed between the gate of the transistor and a portion of the channel region adjacent to the drain region of the transistor, it is possible to reduce the leakage current by preventing a phenomenon in which the threshold voltage is lowered due to the tunneling phenomenon.

According to an embodiment of the inventive concept, by reducing the amount of electric field acting between the gate and the drain region, it is possible to suppress the hot carrier effect (HCE), the data induced barrier leakage (DIBL) phenomenon, and gate induced drain leakage (GIDL) phenomenon caused by the short channel effect.

Such a transistor may be suitable for a high-resolution display panel.

Although the embodiments of the present inventive concept have been described, it is understood that the present inventive concept should not be limited to these embodiments but various changes and modifications can be made by one ordinary skilled in the art within the spirit and scope of the present inventive concept as hereinafter claimed.

What is claimed is:

1. A display panel comprising:
a light emitting element;
a pixel circuit including a first transistor and electrically connected to the light emitting element; and
a first insulating layer,
wherein the first transistor comprises:
a first semiconductor pattern arranged under the first insulating layer and including a first source region, a first drain region, and a first channel region arranged between the first source region and the first drain region, and
a first gate arranged on the first insulating layer and overlapping the first channel region, and
wherein the first insulating layer comprises a first region overlapping a normal region of the first gate and the first source region, and a second region which overlaps a protruding region of the first gate, has a thickness greater than that of the first region, and is disposed close to the first drain region than the first region.

2. The display panel of claim 1, wherein the first region has a uniform thickness and overlaps the first portion of the first gate and the first source region.

3. The display panel of claim 1, wherein the first insulating layer has a uniform thickness in the second region, and
wherein the first region and the second region forms a step in a region overlapping the channel region.

4. The display panel of claim 1, wherein the second region comprises:
a first sub-region having a first thickness and forming a step with the first region; and
a second sub-region having a second thickness larger than the first thickness and forming a step with the first sub-region.

5. The display panel of claim 1, wherein the first insulating layer in the second region has a thickness gradually increasing towards the first drain region.

6. The display panel of claim 1,
wherein the first insulating layer further comprises a third region overlapping the first drain region and having a smaller thickness than the second region, and
wherein the second region forms a step with the third region.

7. The display panel of claim 6, wherein a thickness of the first insulating layer in the third region is the same as the thickness of the first insulating layer in the first region.

8. The display panel of claim 1, wherein, in a cross-sectional view, a length of the second region in a channel length direction is at most half of a length of the first channel region in the channel length direction.

9. The display panel of claim 1, wherein a thickness of the first insulating layer in the second region is at most two times greater than the thickness of the first insulating layer in the first region.

10. The display panel of claim 1, further comprising a second transistor,
wherein the second transistor comprises:
a second semiconductor pattern arranged on the same layer as the first semiconductor pattern and including a second source region, a second drain region, and a second channel region arranged between the second source region and the second drain region, and
a second gate overlapping the second channel region and arranged on the same layer as the first gate, and
wherein the first semiconductor pattern and the second semiconductor pattern include the same material and include any one of polysilicon and oxide semiconductor.

11. The display panel of claim 10, wherein the first region further overlaps a normal region of the second gate and the second source region, and
wherein the second region further overlaps a protruding region of the second gate and is disposed close to the second drain region than the first region overlapping the normal region of the second gate and the second source region.

12. The display panel of claim 10, wherein the first insulating layer has a uniform thickness in a region overlapping the second semiconductor pattern.

13. The display panel of claim 12, wherein the first transistor is a switching transistor and the second transistor is a driving transistor.

14. The display panel of claim 1, further comprising:
an upper insulating layer arranged on the first gate; and
a second transistor,
wherein the second transistor comprises:
a second semiconductor pattern arranged between the first insulating layer and the upper insulating layer and including a second source region, a second drain region, and a second channel region arranged between the second source region and the second drain region, and
a second gate arranged on the upper insulating layer and overlapping the second channel region, and
wherein the first semiconductor pattern includes polysilicon and the second semiconductor pattern includes an oxide semiconductor.

15. The display panel of claim 14, wherein the upper insulating layer comprises a first region overlapping a normal region of the second gate and the second source region, and a second region which overlaps a protruding region of the second gate, has a thickness greater than that of the first region of the upper insulating layer, and is disposed close to the second drain region than the first region of the upper insulating layer.

16. The display panel of claim 14, wherein the upper insulating layer has a uniform thickness in a region overlapping the second semiconductor pattern.

17. The display panel of claim 1, further comprising:
a lower insulating layer arranged under the first semiconductor pattern; and
a second transistor,
wherein the second transistor comprises:
a second semiconductor pattern arranged under the lower insulating layer and including a second source region, a second drain region, and a second channel region arranged between the second source region and the second drain region, and
a second gate arranged between the lower insulating layer and the first insulating layer and overlapping the second channel region,
wherein the lower insulating layer comprises a first region overlapping a normal region of the second gate and the second source region, and a second region which overlaps a protruding region of the second gate, has a thickness greater than that of the first region of the lower insulating layer, and is disposed close to the second drain region than the first region of the lower insulating layer, and
wherein the first semiconductor pattern includes an oxide semiconductor and the second semiconductor pattern includes a silicon semiconductor.

18. The display panel of claim 1, further comprising:
a second insulating layer arranged on the first insulating layer and covering the first gate;
a first connection electrode arranged on the second insulating layer and connected to the first source region through a first contact hole formed in the first insulating layer and the second insulating layer; and
a second connection electrode arranged on the second insulating layer and connected to the first drain region through a second contact hole formed in the first and second insulating layers.

19. A display panel comprising:
a base layer;
a light emitting element arranged on the base layer;
a pixel circuit including a transistor and electrically connected to the light emitting element; and
an insulating layer arranged on the base layer,
wherein the transistor comprises:
a semiconductor pattern arranged between the base layer and the insulating layer and including a source region, a drain region, and a channel region arranged between the source region and the drain region, and
a gate overlapping the channel region and arranged on the insulating layer,
wherein the gate comprises a first edge disposed adjacent to the source region and a second edge disposed adjacent to the drain region, and
wherein a distance from an upper portion of the semiconductor pattern to an upper portion of the first edge is larger than a distance from the upper portion of the semiconductor pattern to an upper portion of the second edge.

20. A method of manufacturing a display panel, comprising:
forming a preliminary semiconductor pattern on a base layer;
forming a preliminary insulating layer on the preliminary semiconductor pattern;
forming an insulating layer including a first region and a second region having a thickness greater than that of the first region through a photolithography process;
forming a gate overlapping a portion of the first region and the second region on the insulating layer; and
forming, from the preliminary semiconductor pattern, a semiconductor pattern including a channel region overlapping the gate and a source region and a drain region which extend in opposite directions with the channel region disposed therebetween,
wherein the second region is disposed close to the drain region than the first region.
